(19) United States
(12) Patent Application Publication
(10) Pub. No.: US 2025/0070093 A1
(43) Pub. Date: Feb. 27, 2025

(54) POWER MODULES AND METHODS FOR ASSEMBLING POWER MODULES

(71) Applicant: Murata Manufacturing Co., Ltd., Kyoto (JP)

(72) Inventors: Laurence McGarry, Los Gatos, CA (US); Michael Patrick Clark, Lunenburg, MA (US); Takahiro Sugimura, Arlington, MA (US); David Giuliano, Bedford, NH (US)

(21) Appl. No.: 18/945,312

(22) Filed: Nov. 12, 2024

Related U.S. Application Data
(63) Continuation of application No. PCT/US2023/066893, filed on May 11, 2023.
(60) Provisional application No. 63/364,674, filed on May 13, 2022.
(60) Provisional application No. 63/364,569, filed on May 12, 2022.

(51) Int. Cl. H01L 25/065; H01L 23/00; H01L 23/367

(52) U.S. Cl. CPC H01L 25/0657; H01L 23/367; H01L 24/16; H01L 2224/16225; H01L 2225/06517; H01L 2924/15311

(57) ABSTRACT

A power module includes a first board comprising a first surface and a second surface opposite to each other and perpendicular to a bottom surface of the power module for mounting the power module to a circuit board, the bottom surface providing electrical connections to the circuit board, a first charge pump assembly mounted on the first surface, the first charge pump assembly comprising a first power conversion circuit configured to convert an input voltage to an output voltage, and a first vertical heatsink structure arranged adjacent to the first charge pump assembly, the first charge pump assembly being placed between the first vertical heatsink structure and the first board.

### CROSS-REFERENCE TO RELATED APPLICATIONS

This application is a continuation of International Patent Application No. PCT/US2023/066893 filed May 11, 2023 and entitled “POWER MODULES AND METHODS FOR ASSEMBLING POWER MODULES,” which claims priority to and the benefit of U.S. Provisional Patent Application No. 63/364,569 filed May 12, 2022 and entitled “POWER CONVERTER PACKAGES, APPARATUS FOR POWER CONVERSION, AND METHODS FOR INTEGRATED CIRCUIT PACKAGING,” and U.S. Provisional Patent Application No. 63/364,674 filed May 13, 2022 entitled “APPARATUS AND METHODS OF FABRICATING A SWITCHED CAPACITOR CIRCUIT,” all of which are incorporated herein by reference in their entirety.

### TECHNICAL FIELD

The present disclosure generally relates to semiconductor and power electronics manufacturing. More particularly, the present disclosure relates to power modules and methods for assembling the power modules.

### BACKGROUND

Semiconductor packages are widely used for protecting an integrated circuit (IC) chip and providing an electrical interface to external circuitry. With the increasing demand for smaller device sizes and higher power densities, packages for power modules are designed to be more compact with increased circuit density. In power devices, power converters, such as charge pump converters, include switches forming a switch network and one or more capacitors to achieve the power conversion and regulate an output voltage or current by switching energy storage elements (e.g., capacitors and/or inductors) between different electrical configurations. The dies and associated passive components often generate significant heat and result in thermal hotspots due to high-power devices within the packages. Accordingly, designing a semiconductor package with sufficient heat dissipation properties to remove heat dissipated within each power device has become a challenge in the field.

### SUMMARY

Embodiments of the present disclosure provide a power module. The power module may include a first board, a first charge pump assembly, and a first vertical heatsink structure. The first board may include a first surface and a second surface opposite to each other and perpendicular to a bottom surface of the power module for mounting the power module to a circuit board. The bottom surface may provide electrical connections to the circuit board. The first charge pump assembly may be mounted on the first surface. The first charge pump assembly may include a first power conversion circuit configured to convert an input voltage to an output voltage. The first vertical heatsink structure may be arranged adjacent to the first charge pump assembly. The first charge pump assembly may be placed between the first vertical heatsink structure and the first board.

Embodiments of the present disclosure provide a power module. The power module may include a bottom surface for mounting the power module to a circuit board, and a plurality of circuit assemblies stacked along a first direction parallel to the bottom surface. The circuit assemblies may provide a plurality of charge pump circuits coupled in parallel and configured to convert an input voltage to an output voltage.

Embodiments of the present disclosure provide a computer device. The computer device may include a motherboard and a power supply unit. The power supply unit may be electrically coupled to the motherboard via electrical connections to deliver power to one or more electrical devices on the motherboard and includes a power module configured to convert an input power to an output power. The power module may include a first board connected to a bottom surface providing electrical connections to the motherboard and comprising a first surface and a second surface opposite to each other and perpendicular to a bottom surface, a first charge pump assembly mounted on the first surface, the first charge pump assembly comprising a first power conversion circuit configured to convert an input voltage to an output voltage; and a first heatsink structure arranged adjacent to the first charge pump assembly, the first charge pump assembly being placed between the first heatsink structure and the first board.

Embodiments of the present disclosure provide a power conversion circuit. The power conversion circuit may include a plurality of switched capacitor circuits coupled in parallel to convert a first voltage to a second voltage. One of the plurality of switched capacitor circuits may include: a plurality of fly capacitors, a plurality of stack switches coupled to positive terminals of the plurality of fly capacitors via a plurality of direct current (dc) nodes, and a plurality of phase switches coupled to negative terminals of the plurality of fly capacitors via a first phase node or a second phase node of the switched capacitor circuit. The switched capacitor circuit may be configured to transition between different states in response to switching of the plurality of stack switches and the plurality of phase switches to convert the first voltage to the second voltage. The plurality of switched capacitor circuits are respectively capable of being arranged in a plurality of circuit assemblies in a power module with a bottom surface for mounting the power module to a circuit board and providing electrical connections. The plurality of circuit assemblies may be stacked along a first direction parallel to the bottom surface.

Embodiments of the present disclosure provide a method for assembling a power module. The method may include: mounting a first charge pump assembly on a first surface of a first board, the first charge pump assembly comprising a first power conversion circuit configured to convert an input voltage to an output voltage, mounting the first board and positioning the first surface to be perpendicular to a bottom surface of the power module.

Additional features and advantages of the disclosed embodiments will be set forth in part in the following description, and in part will be apparent from the description, or may be learned by practice of the embodiments. The features and advantages of the disclosed embodiments may be realized and attained by the elements and combinations set forth in the claims.

### BRIEF DESCRIPTION OF THE DRAWINGS

Embodiments and various aspects of the present disclosure are illustrated in the following detailed description and the accompanying figures. It is noted that, in accordance with standard practice in the industry, various features are not drawn to scale. In fact, the dimensions of the various features may be arbitrarily increased or reduced for clarity of discussion.

FIG. 1 is a side view of an exemplary power module, in accordance with some embodiments of the present disclosure.

FIG. 2 is a side view of an exemplary power module, in accordance with some embodiments of the present disclosure.

FIG. 3 is a side view of an exemplary computer device, in accordance with some embodiments of the present disclosure.

FIG. 4 is a circuit diagram illustrating an exemplary power conversion circuit, in accordance with some embodiments of the present disclosure.

FIG. 5 is a diagram illustrating an exemplary charge pump assembly, in accordance with some embodiments of the present disclosure.

FIG. 6 is a diagram illustrating another exemplary charge pump assembly, in accordance with some embodiments of the present disclosure.

FIG. 7A and FIG. 7B are diagrams illustrating exemplary power modules assembled as modules outside of a customer PCB, in accordance with some embodiments of the present disclosure.

FIG. 8A and FIG. 8B are diagrams illustrating exemplary power modules using surface mount, in accordance with some embodiments of the present disclosure.

FIG. 9A-FIG. 9D are diagrams illustrating exemplary lead trim and form process, in accordance with some embodiments of the present disclosure.

FIG. 10A and FIG. 10B are diagrams illustrating exemplary package assemblies using castellated edge plated leads, in accordance with some embodiments of the present disclosure.

FIGS. 11A-11G are diagrams illustrating exemplary stages in an embedded die packaging to achieve the power module, in accordance with some embodiments of the present disclosure.

FIG. 12 is a flowchart of a method for assembling a power module, in accordance with some embodiments of the present disclosure.

FIG. 13-FIG. 20 are diagrams illustrating exemplary stages in the method of FIG. 12 for assembling the power module, in accordance with some embodiments of the present disclosure.

FIG. 21 is a diagram illustrating an exemplary power module as the final product, in accordance with some embodiments of the present disclosure.

FIG. 22 is a flowchart of an alternative method for assembling a power module, in accordance with some embodiments of the present disclosure.

FIG. 23-FIG. 31 are diagrams illustrating exemplary stages in the method of FIG. 22 for assembling the power module, in accordance with some embodiments of the present disclosure.

FIG. 32 is a diagram illustrating an exemplary power module as the final product, in accordance with some embodiments of the present disclosure.

FIG. 33 is a flowchart of an alternative method for assembling a power module, in accordance with some embodiments of the present disclosure.

FIG. 34-FIG. 41 are diagrams illustrating exemplary stages in the method of FIG. 33 for assembling the power module, in accordance with some embodiments of the present disclosure.

FIG. 42 is a diagram illustrating an exemplary power converter, in accordance with some embodiments of the present disclosure.

FIGS. 43A-43D are diagrams illustrating exemplary structures, in accordance with some embodiments of the present disclosure.

FIGS. 44A-44C are diagrams illustrating exemplary passive device layers, in accordance with some embodiments of the present disclosure.

FIG. 44D is a diagram illustrating an exemplary active device layer with the molded interconnect substrate, in accordance with some embodiments of the present disclosure.

FIG. 45A is a diagram illustrating an exemplary structure, in accordance with some embodiments of the present disclosure.

FIGS. 45B, 45C, and 45D are a side view, a bottom view, and a top view, respectively, of relative spatial arrangement of switches and capacitors formed in the structure of FIG. 45A, in accordance with some embodiments of the present disclosure.

FIG. 46 is a diagram illustrating another exemplary structure, in accordance with some embodiments of the present disclosure.

FIG. 47 is a diagram illustrating another exemplary structure including heat spreader layers, in accordance with some embodiments of the present disclosure.

### DETAILED DESCRIPTION

The following disclosure provides many exemplary embodiments, or examples, for implementing different features of the provided subject matter. Specific simplified examples of components and arrangements are described below to explain the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this document, the term “coupled” may also be termed as “electrically coupled”, and the term “connected” may be termed as “electrically connected”. “Coupled” and “connected” may also be used to indicate that two or more elements cooperate or interact with each other.

Various embodiments of the present disclosure will be described with respect to embodiments in a specific context, namely a charge pump circuit. As used in this disclosure, the term “charge pump” refers to a switched-capacitor network configured to convert an input voltage to an output voltage. Examples of such charge pumps include cascade multiplier, Dickson, ladder, series-parallel, Fibonacci, and Doubler switched-capacitor networks, all of which may be configured as a multi-phase or a single-phase network. The concepts in the disclosure may also apply, however, to other types of power IC devices using 2.5D/3D packaging technologies.

In the context of the present disclosure, power converting circuits that convert a higher input voltage power source to a lower output voltage level are commonly known as step-down or buck converters, because the converter is “bucking” the input voltage. Power converting circuits that convert a lower input voltage power source to a higher output voltage level are commonly known as step-up or boost converters, because the converter is “boosting” the input voltage. In addition, some power converters, commonly known as “buck-boost converters,” may be configured to convert the input voltage power source to the output voltage with a wide range, in which the output voltage may be either higher than or lower than the input voltage. In various embodiments, a power converter may be bidirectional, being either a step-up or a step-down converter depending on how a power source is connected to the converter. In some embodiments, an AC-DC power converter can be built up from a DC-DC power converter by, for example, first rectifying an AC input voltage to a DC voltage and then applying the DC voltage to a DC-DC power converter.

Integrated circuits (ICs) and the semiconductor packages in accordance with the present disclosure may be used alone or in combination with other components, circuits, devices, and packages. For example, the packages may be combined with other components, such as on a printed circuit board (PCB), to form part of a power module, a power converter device, a power supply system, or an end product such as a cellular telephone, laptop computer, or electronic tablet, or to form a higher-level module or system which may be used in a wide variety of products, such as energy management systems for computing devices, industrial devices, medical devices, large-scale data centers, vehicle electrical systems in automotive applications, etc.

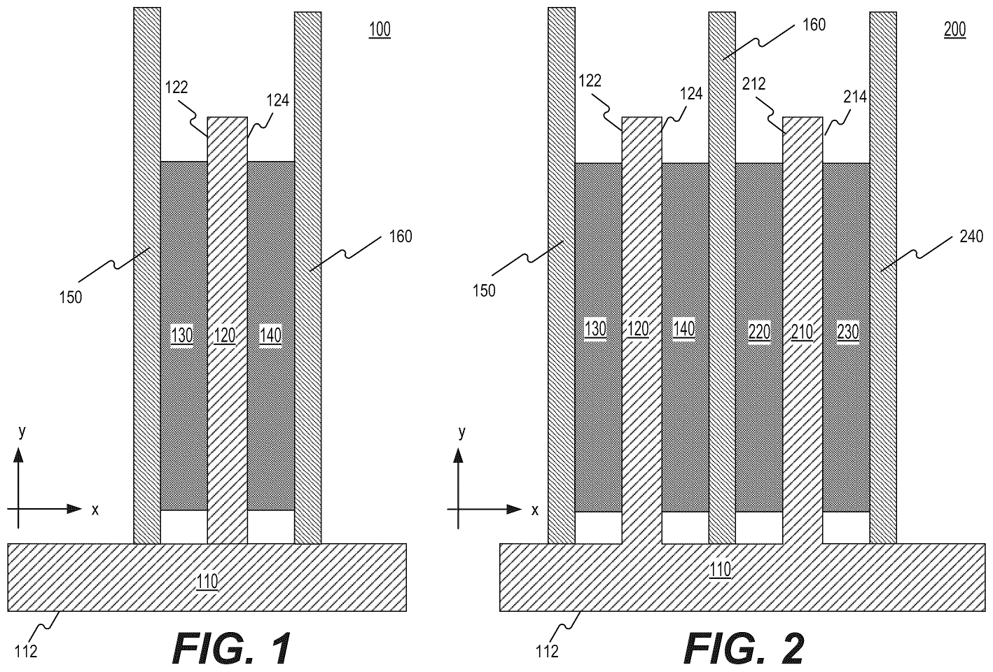

FIG. 1 is a side view of an exemplary power module 100, in accordance with some embodiments of the present disclosure. As used herein, a power module may refer to a physical unit or apparatus containing power and electronic components of a power converter circuit. In the power module 100 of FIG. 1, modules and ICs forming one or more charge pump circuits can be vertically mounted and horizontally stacked or spaced on a carrier board. As shown in FIG. 1, the power module 100 includes a carrier board 110, a first board 120, a first charge pump assembly 130, a second charge pump assembly 140, a first vertical heatsink structure 150, and a second vertical heatsink structure 160. In various embodiments, the first charge pump assembly 130 or the second charge pump assembly 140 may be a system-in-package (SiP) assembly, but the present disclosure is not limited thereto.

The carrier board 110 includes a bottom surface 112 for mounting the power module 100 to a circuit board (e.g., a customer motherboard). The bottom surface may provide electrical connections to the circuit board to receive and/or transmit power, data, or control signals and interact with external circuits in other module(s) mounted on the circuit board or electrically coupled to the circuit board. For example, the carrier board 110 may connect to the circuit board via slots with gold contacts, which can be used in various applications such as peripheral component interconnect express (PCIE) cards. In some embodiments, the carrier board 110 may be configured to provide a land grid array or a ball grid array on the bottom surface 112. In some other embodiments, the carrier board 110 may include a leadframe structure. For example, the carrier board 110 may provide Leadframe Foot Array on the bottom side, using through-holes of a surface mount leadframe design. In some other embodiments, the power module 100 may also use a straight vertical coupling board to horizontally mount the power module 100 onto the motherboard.

The first board 120 may be vertically mounted and connected to the carrier board 110. Alternatively stated, the first board 120 provides a first surface 122 and a second surface 124 opposite to each other and perpendicular to the bottom surface 112 of the carrier board 110. As shown in FIG. 1, the first charge pump assembly 130 may be mounted on the first surface 122. The first charge pump assembly 130 may include a first power conversion circuit (e.g., a charge pump circuit) configured to convert an input voltage to an output voltage. For example, the first board 120 may include a PCB laminate structure, and the first charge pump assembly 130 may include one or more dies and capacitors mounted on the PCB laminate structure. The one or more dies may include switching elements (e.g., power field effect transistors (FETs)) for the charge pump circuit. In some embodiments, the first charge pump assembly 130 may further include one or more heat spreader layers attached to the one or more dies.

The first board 120 and the first charge pump assembly 130 can also be implemented by different approaches according to practical needs. For example, in some embodiments, the first board 120 may include a PCB laminate structure, and the first charge pump assembly 130 may include one or more bumped dies attached on the PCB laminate structure. In some other embodiments, the first charge pump assembly 130 may include one or more dies embedded in the PCB laminate structure or one or more dies mounted on a leadframe. In yet some other embodiments, the first board 120 may be a rigid PCB section of a rigid-flex board. The rigid-flex board is bent and mounted to the carrier board 110.

Similarly, the second charge pump assembly 140 may be mounted on the second surface 124. The second charge pump assembly 140 may include a second power conversion circuit (e.g., another charge pump circuit) configured to convert the input voltage to the output voltage. For example, the second charge pump assembly 140 may include one or more dies and capacitors mounted on the PCB laminate structure. In some embodiments, the first power conversion circuit in the first charge pump assembly 130 and the second power conversion circuit in the second charge pump assembly 140 may be electrically coupled to each other in parallel via electrical connection features included in the first board 120 and/or the carrier board 110. Other features of the second charge pump assembly 140 may be similar to those of the first charge pump assembly 130, and thus are not repeated herein for the sake of brevity.

One or more heatsink structures can be arranged in the power module 100 to remove heat from the charge pump circuits. For example, in FIG. 1, the first vertical heatsink structure 150 is arranged adjacent to the first charge pump assembly 130 and the second vertical heatsink structure 160 may be arranged adjacent to the second charge pump assembly 140.

Accordingly, the first charge pump assembly 130 may be sandwiched and placed between the first vertical heatsink structure 150 and the first board 120. The second charge pump assembly 140 may be placed between the second vertical heatsink structure 160 and the first board 120. By the mounting and stacking/spacing of charge pump assemblies in the horizontal direction, additional heatsinks (e.g., vertical heatsink structures 150, 160) can be placed on each side of each charge pump module (e.g., first charge pump assembly 130 or second charge pump assembly 140). Compared to the charge pump modules stacked in the vertical direction, in the power module 100, heatsinks can be attached to charge pump assemblies or modules equally to avoid the thermal imbalance issues (e.g., one charge pump assembly having a greater temperature than another) that occur in the traditional design, where the heatsink is generally only attached to the uppermost charge pump assembly in the vertically stacked approach.

Specifically, the vertical heatsink structures 150 and 160 can achieve even heat distribution (e.g., even heat distribution among charge pump assemblies or modules) and effective heat output. Because a thermal imbalance may also cause a current imbalance when a large thermal gradient is present, the power module 100 of FIG. 1 can improve thermal stability and reduce the level of de-rating required during the operation. The horizontal stacking design in the power module 100 is suitable for various applications that are highly sensitive to efficiency and heat management but with low height sensitivity (e.g., 6-8 mm), such as power devices used in data centers, accelerator card applications, etc.

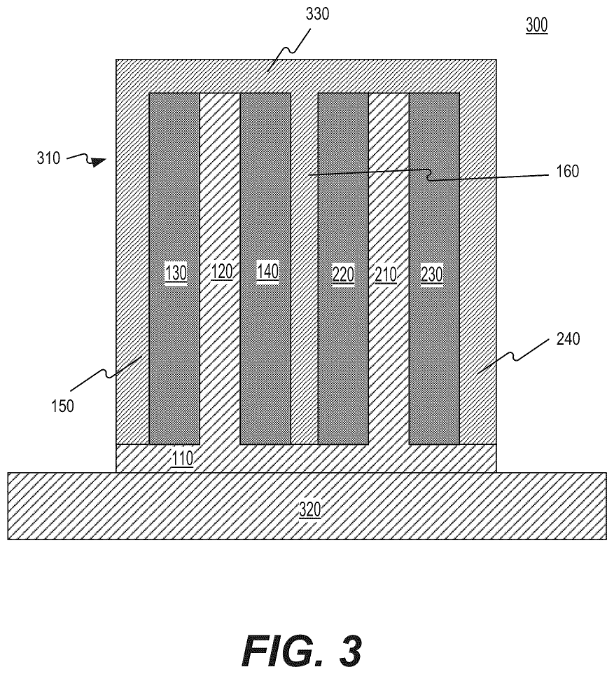

In addition, it is possible to increase the number of the stacking charge pump assemblies to provide a higher effective output power level for high-power output applications (e.g., 200 W to 300 W, or up to 1000 W). FIG. 2 is a side view of an exemplary power module 200, in accordance with some embodiments of the present disclosure. Similar to the embodiments of FIG. 1, in the power module 200, modules and ICs forming one or more charge pump circuits can also be vertically mounted and horizontally stacked or spaced on the carrier board (e.g., a motherboard). Compared to the power module 100 of FIG. 1, the power module 200 may further include a second board 210 connected to the carrier board 110 and arranged parallel to the first board 120, a third charge pump assembly 220, a fourth charge pump assembly 230, and a third vertical heatsink structure 240.

As shown in FIG. 2, the second board 210 may provide a third surface 212 and a fourth surface 214 opposite to each other and perpendicular to the bottom surface 112 of the carrier board 110. The third charge pump assembly 220 may be mounted on the third surface 212, and the fourth charge pump assembly 230 may be mounted on the fourth surface 214. Similar to the first and the second charge pump assemblies 130, 140, the third charge pump assembly 220 may include a third power conversion circuit configured to convert the input voltage to the output voltage, and the fourth charge pump assembly 230 may include a fourth power conversion circuit configured to convert the input voltage to the output voltage. In some embodiments, the third and the fourth power conversion circuits in charge pump assemblies 220 and 230 can be electrically coupled in parallel to the first and the second power conversion circuits in charge pump assemblies 130 and 140, via electrical connection features included in the first board 120, the second board 210, and the carrier board 110.

The second vertical heatsink structure 160 may be sandwiched and arranged between the second charge pump assembly 140 and the third charge pump assembly 220. The third vertical heatsink structure 240 may be arranged adjacent to the fourth charge pump assembly 230, so that the fourth charge pump assembly 230 may be sandwiched and placed between the third vertical heatsink structure 240 and the second board 210.

As one skilled in the art would understand, the arrangements shown in FIG. 1 and FIG. 2 are merely examples and not meant to limit the present disclosure. In various embodiments, three or more boards can be located and vertically mounted on the carrier board, with corresponding charge pump circuit assemblies mounted on one or both sides of the boards to achieve the horizontal stacking arrangements of the charge pump circuit assemblies. In other words, a plurality of circuit assemblies (e.g., charge pump assemblies 130, 140, 220, and 230) can be stacked along a first direction (e.g., x-direction) parallel to the bottom surface 112 of the carrier board 110. The circuit assemblies provide corresponding charge pump circuits coupled in parallel and configured to convert the input voltage to the output voltage.

In particular, the circuit assemblies are mounted on corresponding substrates (e.g., the double-sided sub-board such as the first board 120 in FIG. 1 and FIG. 2 and the second board 210 in FIG. 2) connected to the carrier board 110 and aligned along the first direction (e.g., x-direction). Each substrate may provide two surfaces (i.e., a first surface and a second surface) opposite to each other and perpendicular to the bottom surface 112 of the carrier board 110, and each circuit assembly may be mounted on one of the surfaces of the corresponding substrate. Multiple heatsink structures can be provided in the stacking structure in the power module. Specifically, a heatsink structure can be placed between two adjacent circuit assemblies along the first direction. In some embodiments, the charge pump assemblies may be molded assemblies. In some other embodiments, the charge pump assemblies may be unmolded.

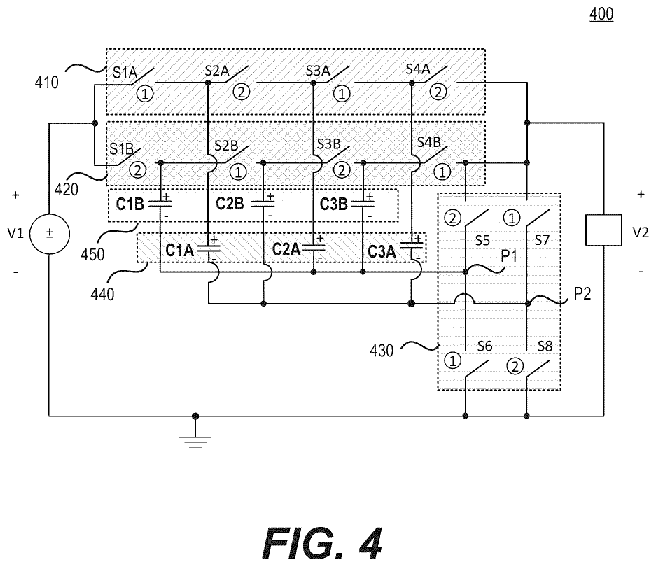

FIG. 3 is a side view of an exemplary computer device 300, in accordance with some embodiments of the present disclosure. The computer device 300 may include a power supply unit 310 and a motherboard 320. The power supply unit 310 is electrically coupled to the motherboard 320 via electrical connections to deliver power to one or more electrical devices (not shown) on the motherboard 320. The power supply unit 310 includes a power module configured to convert an input power to an output power to meet the voltage requirements of the electrical devices on the motherboard 320.

As shown in FIG. 3, similar to the power module 200 of FIG. 2, the power module in the power supply unit 310 may also include the carrier board 110 with a bottom surface providing the electrical connections to the motherboard 320, the first board 120 and the second board 210, which may both connected to the carrier board 110. The first board 120 may include a first surface and a second surface opposite to each other and perpendicular to the bottom surface, in which the first and the second charge pump assemblies 130, 140 may be respectively mounted on the first and the second surfaces. The second board 210 may include a third surface and a fourth surface opposite to each other and perpendicular to the bottom surface, in which the third and the fourth charge pump assemblies 220, 230 may be respectively mounted on the third and the fourth surfaces. The charge pump assemblies 130, 140, 220, and 230 respectively may include corresponding power conversion circuits configured to convert an input voltage to an output voltage. The first heatsink structure 150 may be arranged adjacent to the first charge pump assembly 130 such that the first charge pump assembly 130 may be placed between the first heatsink structure 150 and the first board 120. The second heatsink structure 160 may be placed between the charge pump assemblies 140 and 220. The third heatsink structure 240 may be arranged adjacent to the fourth charge pump assembly 230 such that the fourth charge pump assembly 230 may be placed between the third heatsink structure 240 and the second board 210.

Compared to the power module 200 of FIG. 2, the power module in the power supply unit 310 of FIG. 3 may further include a horizontal heatsink structure 330 connected to the vertical heatsink structures 150, 160, and 240 to form a complete heatsink unit to facilitate heat transfer and improve the thermal balance among modules and circuit assemblies in order to avoid the thermal issues mentioned above. As one would appreciate, the heatsink structure in various embodiments can be scaled easily depending on the number of substrates or charge pump units connected in parallel. In some embodiments, the heatsink unit of the power module may directly connect to a system heatsink for the heat dissipation. As shown in FIG. 3, the vertical heatsink structures 150, 160, and 240 may be configured to conduct the generated heat to the top (or the bottom) of the power module. In some embodiments, the vertical heatsink structures 150, 160, and 240 may be discrete heatsinks used in conjunction with the heat spreader from the die backside to the heatsink. In some embodiments, an embedded die may integrate the heatsink structures into the package format. Thermal Interface Material (TIM) can be applied between the heatsink structures 150, 160, and 240 and the charge pump assemblies 130, 140, 220, and 230 to eliminate thermal gaps. Conductive thermal epoxy may be used to reduce thermal interface resistances. In various embodiments, the heatsink may be planar plates, or have stamped and formed shapes.

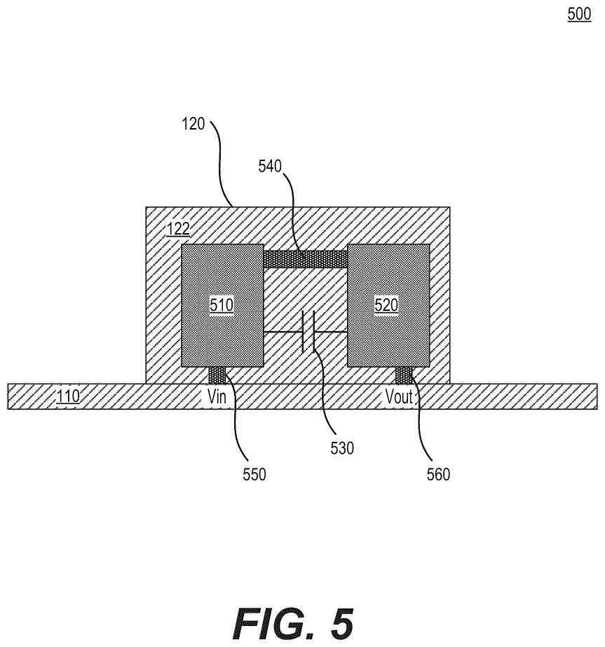

FIG. 4 is a circuit diagram illustrating an exemplary power conversion circuit 400, in accordance with some embodiments of the present disclosure. As shown in FIG. 4, in some embodiments, the power conversion circuit 400 may be a multi-phase switched capacitor circuit, such as a two-phase variant of a Dickson charge pump, also known as a cascade multiplier. In some embodiments, the power conversion circuit 400 of FIG. 4 can be used in any of the charge pump assemblies 130, 140, 220, and 230 in the power module 100, 200 or 300 of any of FIGS. 1-3, but the present disclosure is not limited thereto. It is appreciated that, in various embodiments, the switched capacitor circuit may also be single phase or multiple phase circuit, and designed based on a desired conversion ratio. In the embodiments of FIG. 4, a 4:1 conversion ratio may be obtained. In general, within a Dickson topology, different conversion ratios V1/V2 (e.g., a 3:1 conversion ratio, a 5:1 conversion ratio, etc.), where V1 is a first voltage (e.g., an input DC voltage) and V2 is a second voltage (e.g., an output DC voltage), may be obtained by using different numbers of capacitors and different numbers of switches. As the magnitude of the desired conversion ratio increases, the number of capacitors and switches used in a power converter may increase.

In the embodiments of FIG. 4, the power conversion circuit 400 may include stack switches 410 (e.g., power FETs) for a first phase, stack switches 420 (e.g., power FETs) for a second phase, phase switches 430 (e.g., power FETs) shared by both phases, a first set of capacitors 440, including first capacitors C1A, C2A, and C3A, associated with the first phase and connected to the stack switches 410, and a second set of capacitors 450, including second capacitors C1B, C2B, and C3B, associated with the second phase and connected to the stack switches 420. The stack switches 410 associated with the first phase may include switches S1A, S2A, S3A, and S4A. The stack switches 420 associated with the second phase may include switches S1B, S2B, S3B and S4B. The phase switches 430 may include switches S5, S6, S7, and S8. Accordingly, the power conversion circuit 400 provides a switching network that may cause transitions between first and second states, depending on which of these switches are open and which ones are closed. A first switch configuration may cause the switched capacitor network to transition from the first state to the second state. A second switch configuration causes the switched capacitor network to transition from the second state to the first state. As a result of the switches causing the switched capacitor network to switch between these states, the capacitors 440 and 450 may be charged or discharged in a charge pump cycle to complete the power conversion and transfer the power from the supply to the load.

In the design shown in FIG. 4, the switching network may include two switch chains, i.e., switches connected in series. Particularly, stack switches S1A, S2A, S3A, and S4A may form one switch chain associated with the first phase, while stack switches S1B, S2B, S3B, and S4B may form another switch chain associated with the second phase. Stack switches S1A, S2A, S3A, and S4A may be respectively coupled to positive terminals of the first capacitors C1A, C2A, and C3A associated with the first phase via corresponding dc nodes. Similarly, stack switches S1B, S2B, S3B, and S4B may be respectively coupled to positive terminals of the second capacitors C1B, C2B, and C3B associated with the second phase via corresponding dc nodes.

Phase switches S5 and S6 may be connected to negative terminals of the first and second capacitors C1B, C2A, and C3B via a first phase node P1 while phase switches S7 and S8 may be connected to negative terminals of the first and second capacitors C1A, C2B, and C3A via a second phase node P2. In other words, the first phase node P1 may be coupled to negative terminals of a first subset of the first capacitors (e.g., capacitor C2A) and a first subset of the second capacitors (e.g., capacitors C1B and C3B), while the second phase node P2 may be coupled to negative terminals of a second subset of the first capacitors (e.g., capacitors C1A and C3A) and a second subset of the second capacitors (e.g., capacitor C2B).

During the operation, switches S1A, S2B, S3A, S4B, S6, and S7, which are marked as group 1 in FIG. 4, and the switches S1B, S2A, S3B, S4A, S5 and S8, which are marked as group 2 in FIG. 4, may be in complementary states. For example, in a first state, the switches S1A, S2B, S3A, S4B, S6, and S7 may be open and the switches S1B, S2A, S3B, S4A, S5 and S8 may be closed, in response to the commands from the controller circuit. In a second state following the first state, the switches S1A, S2B, S3A, S4B, S6, and S7 may be closed and the switches S1B, S2A, S3B, S4A, S5 and S8 may be open, in response to the commands from the controller circuit. Furthermore, a dead-time interval may exist between the first state and the second state. During the dead-time interval, all the switches are open, which ensures a clean transition between the two switch states. It would be understood that the present disclosure is not limited to such a ratio or type of conversion circuit. In various embodiments, a step-down or a step-up configuration may be applied to all possible charge pump ratios.

In other embodiments, various circuit topologies can be used in the present disclosure to form different types of power conversion circuits, such as a hybrid converter, a resonant switched capacitor converter, or a multilevel power converter including transistors, capacitors, and one or more inductors as energy storage elements, or a converter with an LC filter coupled with the switched capacitor network to promote adiabatic charging or discharging. Particularly, hybrid converters, such as multi-level power converters or series capacitor buck converters, also include a switched capacitor circuit combined with different topologies.

In some embodiments, one charge pump assembly mounted on one side of the corresponding substrate (e.g., the first board 120 and the second board 210) may include two or more integrated circuits (ICs). By providing power switches integrated into different packages, the total routing resistance can be reduced, and improved power efficiency of the charge pump can be achieved.

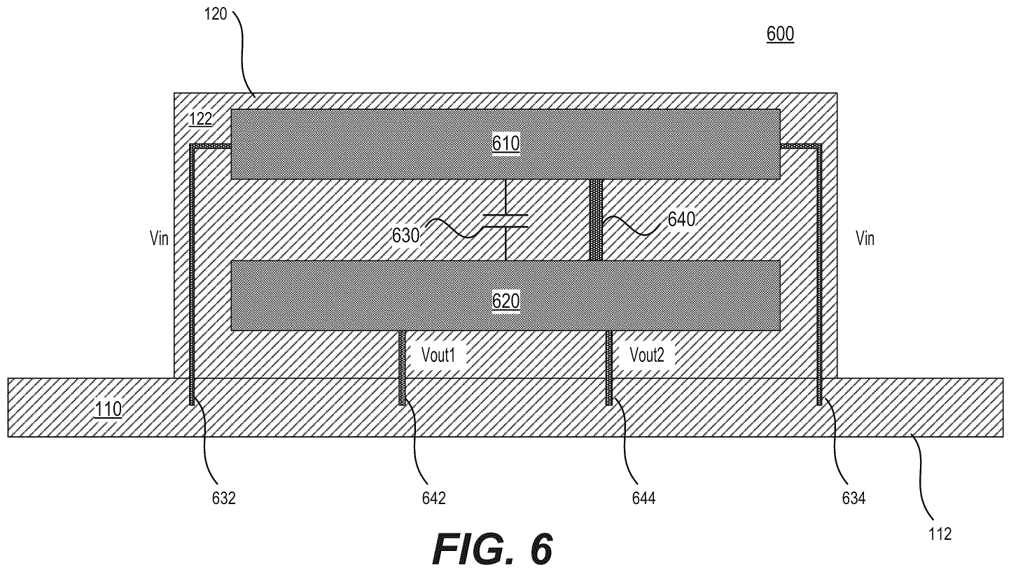

FIG. 5 is a diagram illustrating an exemplary charge pump assembly 500, in accordance with some embodiments of the present disclosure. For ease of understanding, the first charge pump assembly 130 in FIG. 1 will be used as an example to explain the structure of a power conversion circuit (e.g., power conversion circuit 400 in FIG. 4) divided into two or more integrated circuits (ICs) as illustrated in the charge pump assembly 500, but the present disclosure is not limited thereto. The charge pump assembly 500 can be applied to any of the charge pump assemblies discussed in the above embodiments.

As shown in FIG. 5, the charge pump assembly 500 may include a first integrated circuit (IC) 510, a second integrated circuit (IC) 520, and fly capacitors 530 (e.g., capacitors 440 and 450 in FIG. 4) of the power conversion circuit. The first IC 510 and the second IC 520 may both mounted on the same surface (e.g., the first surface 122). The first IC 510 may include a plurality of stack switches (e.g., stack switches 410 and 420 in FIG. 4) of the power conversion circuit 400 in FIG. 4. The second IC 520 can be electrically connected to the first IC 510 via a bus bar 540. The second IC 520 may include a plurality of phase switches (e.g., phase switches 430 in FIG. 4) of the power conversion circuit 400 in FIG. 4. The fly capacitors 530 may be coupled between the first integrated circuit 510 and the second integrated circuit 520.

Accordingly, high current paths from fly capacitors 530 to power switches can be minimized and reduce the overall routing resistance. The power flow within the charge pump assembly 500 can be optimized via a shortened path from a power input to a power output on the carrier board 110, via shortened power input line 550 connected to the first IC 510 and shortened power output line 560 connected to the second IC 520. Compared to the use of bus bars to connect a single IC, the total copper loss of the power circuit can be reduced in the charge pump assembly 500 because of the reduced routing resistance. In addition, the die size of the first IC 510 and the second IC 520 can be reduced accordingly, and the overall costs of the first IC 510 and the second IC 520 compared to a single IC may also be reduced. In some embodiments, the charge pump assembly 500 in FIG. 5 can provide more available IC pins for interconnections by using separate ICs for power FET devices.

In some embodiments, the first IC 510 may further include a controller configured to control the stack switches and the phase switches in the first IC 510 and/or the second IC 520. In some other embodiments, the charge pump assembly 500 may also provide the controller in a separate IC, with 2 FET IC dies with lateral FETs. For example, a controller in the separate IC can be mounted on the other surface (e.g., the second surface 124 opposite to the first surface 122) and configured to control the stack switches and the phase switches in the first IC 510 and/or the second IC 520. In various embodiments, other FET partitioning arrangements may be considered to achieve an optimized performance according to actual needs.

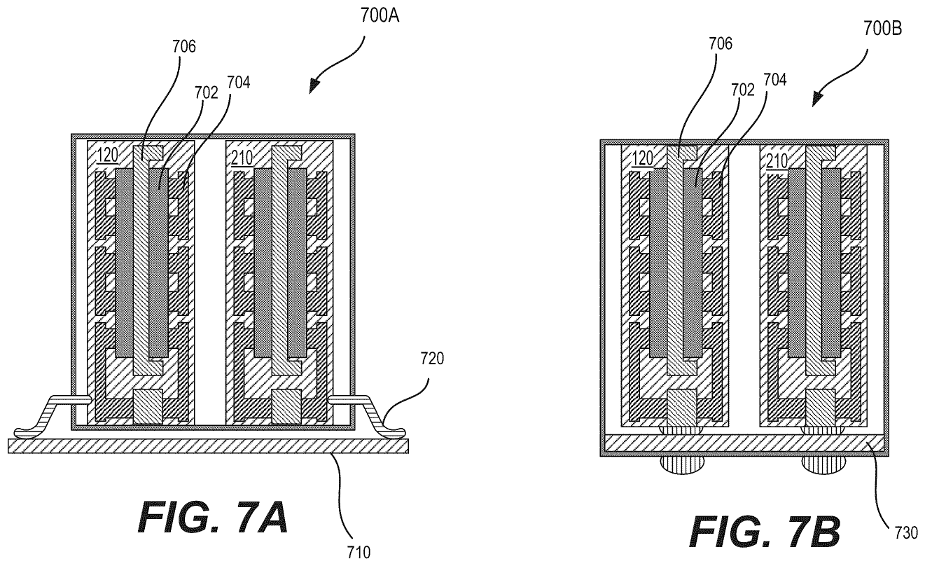

FIG. 6 is a diagram illustrating another exemplary charge pump assembly 600, in accordance with some embodiments of the present disclosure. Similar to the charge pump assembly 500 in FIG. 5, the power conversion circuit (e.g., power conversion circuit 400 in FIG. 4) can be divided into two or more ICs 610 and 620 in the charge pump assembly 600. In some embodiments, one or more of the ICs 610 and 620 can use a Flip-Chip on Leadframe (FCOL) semiconductor packaging structure. The charge pump assembly 600 can be applied to any of the charge pump assemblies discussed in the above embodiments. Specifically, the charge pump assembly 600 may include the first IC 610, the second IC 620, and fly capacitors 630 (e.g., capacitors 440 and 450 in FIG. 4) of the power conversion circuit. The first IC 610 and the second IC 620 may both be mounted on the same surface (e.g., the first surface 122). The first IC 610 may include a plurality of stack switches (e.g., stack switches 410 and 420 in FIG. 4) of the power conversion circuit 400 in FIG. 4. The second IC 620 can be electrically connected to the first IC 610 via a bus bar 640. The second IC 620 may include a plurality of phase switches (e.g., phase switches 430 in FIG. 4) of the power conversion circuit 400 in FIG. 4. The fly capacitors 630 may be coupled between the first IC 610 and the second IC 620.

Compared to ICs 510 and 520 aligned horizontally in FIG. 5, ICs 610 and 620 in FIG. 6 are arranged vertically. In some embodiments, the IC 620 including phase FETs is placed at the bottom, while the IC 610 including stack FETs is placed at the top. Alternatively stated, in some embodiments, the distance between the first IC 610 and the bottom surface 112 is greater than the distance between the second IC 620 and the bottom surface 112. In addition, the charge pump assembly 600 may provide two power input lines 632, 634 connecting the carrier board 110 to the first IC 610 for receiving the input voltage (e.g., the first voltage V1 in FIG. 4) from the carrier board 110, and two power output lines 642 and 644 connecting the second IC 620 to the carrier board 110 for respectively outputting a first output voltage and a second output voltage (e.g., the second voltage V2 in FIG. 4) outputted by the second IC 620 to the carrier board 110.

Similar to the embodiments of FIG. 5, the first IC 610 may further include a controller configured to control the stack switches and the phase switches in the first IC 610 and/or the second IC 620. In some other embodiments, the charge pump assembly 500 may also provide the controller at the backside of the board (e.g., mounted on the other surface (e.g., the second surface 124 opposite to the first surface 122)) to control the stack switches and the phase switches in the first IC 610 and/or the second IC 620. Other FET partitioning arrangements may also be considered to achieve an optimized performance according to actual needs. Accordingly, an optimized thermal performance can be achieved by the optimal positioning of the discrete FETs, which allows a higher power output during the operation without triggering the over-temperature or thermal imbalance.

It is noted that, in various embodiments of the present disclosure, the interconnection can be achieved in various ways. For example, in some embodiments, multiple vertical charge pump layers may be arranged perpendicular to the main PCB. Die(s) and passive components can be surface mounted onto the PCB laminate, either single or double-sided. In the SiP or module format, the die(s) and passive components can be molded or unmolded. In some other embodiments, the die(s) may be embedded dies in laminate with bumped edges on a bottom horizontal edge, or embedded dies in laminate with surface mount on a vertical surface using Land Grid Array or Ball Grid Array. In some other embodiments, die(s) and passive components can also be mounted onto a multichip module leadframe assembly. In some embodiments, the vertical coupling boards for the charge pump and circuit interconnect (e.g., the first and second boards) may be discrete boards for SIP, SMT and leadframe format. Die(s) and passive components are integrated into the laminate PCB. Heavy copper metal layers of the PCB can function as the heat spreaders to provide vertical heat dissipation paths.

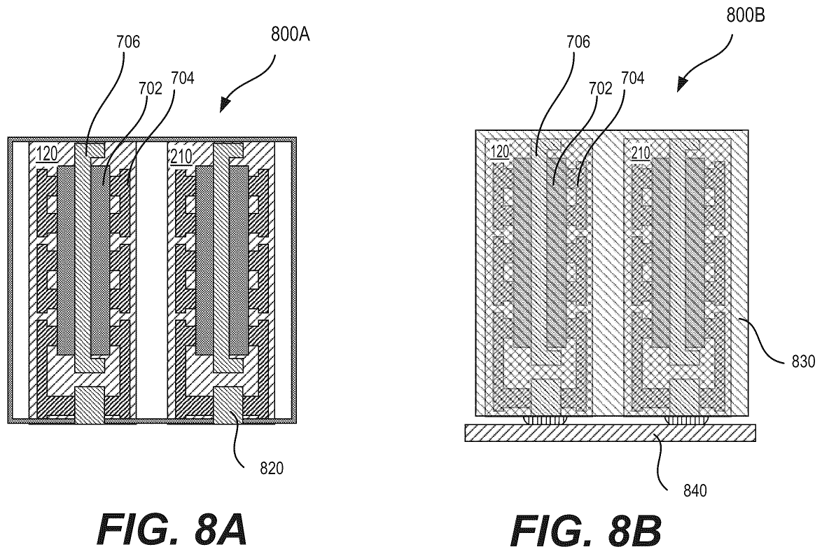

FIG. 7A and FIG. 7B are diagrams illustrating exemplary power modules 700A and 700B assembled as modules outside of a customer PCB, in accordance with some embodiments of the present disclosure. In the embodiments of FIG. 7A and FIG. 7B, a standard Surface Mount Technology (SMT) process can be applied for the assembly. In some embodiments, the carrier board 110 may use Land Grid Array (LGA) or Ball Grid Array (BGA) to connect to the customer PCB 710. In some embodiments, various lead or lead-free soldering can be used. In the embodiments of FIG. 7A, formed leads 720 can be used without a carrier PCB. In the embodiments of FIG. 7B, the carrier PCB 730 is used when internal and/or external non-leaded interconnect is needed. As shown in FIGS. 7A and 7B, power modules 700A and 700B may include dies 702, interconnects 704, and structures 706 embedded in the first board 120 and the second board 210, and use embedded die packaging technology.

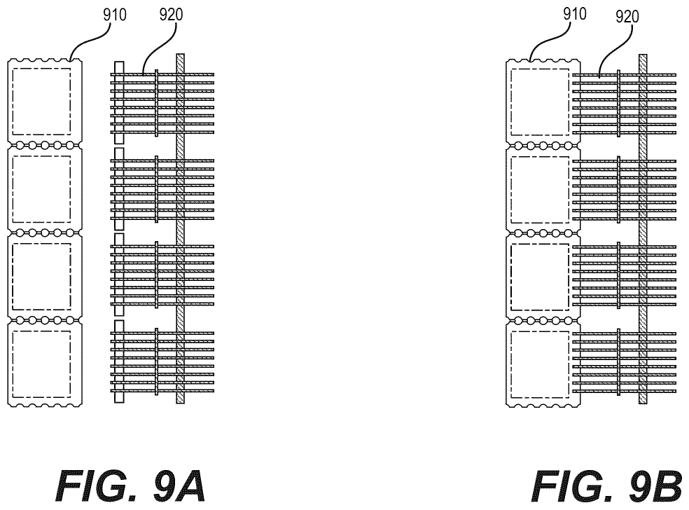

FIG. 8A and FIG. 8B are diagrams illustrating exemplary power modules 800A and 800B using surface mount, in accordance with some embodiments of the present disclosure. In some embodiments, the aEASI package can be suitable for power electronics applications to reduce power loss and high thermal dissipation. The a-EASI applied metal lead frame can provide a short connection path to die placement and archive a high thermal dissipation. As shown in FIG. 8A and FIG. 8B, the power modules 800A and 800B can be molded to provide embedded dies 702 and the leadframe with the exposed and plated leads 820. As shown in FIG. 8B, the heat sink structure 830 can also be exposed to facilitate thermal dissipation, and the SMT process can be applied for mounting the power module 800B on a motherboard 840.

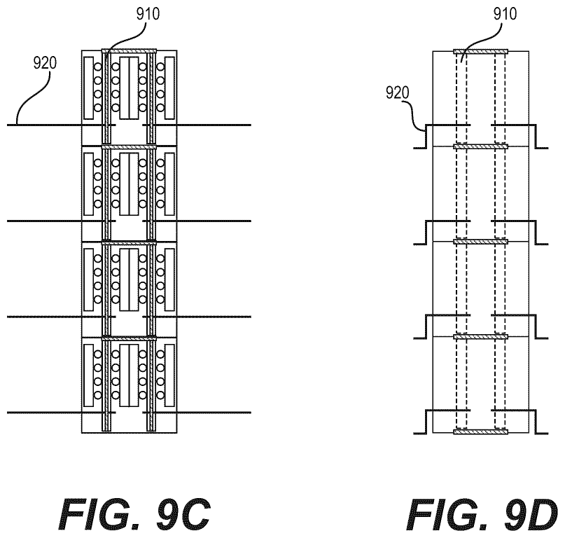

FIG. 9A-FIG. 9D are diagrams illustrating exemplary lead trim and form process, in accordance with some embodiments of the present disclosure. In some embodiments, copper alloy and heavy gauge lead frame can be used in the lead fabrication. After the IC assembly and the molding process, leads can be formed and trimmed for surface mount or through-hole components. As shown in FIG. 9A-FIG. 9D, package assemblies can be fabricated in a strip format. In some embodiments, the packages may be wafer level chip scale packages (WLCSPs). FIG. 9A illustrates the package assemblies applying a lead-through-board technology, in which leads on the leadframe 920 are inserted through holes in the PCB(s) 910. FIG. 9B illustrates the package assemblies applying a lead-on-board technology, in which leads on the leadframe 920 are mounted on the PCB(s) 910. As shown in FIG. 9C, the package assemblies may apply a lead-through-board technology, to obtain leads providing electrical connections to the PCB(s) 910. After the assembly and molding process is completed, as shown in FIG. 9D, a bend and trim process can be applied to form the shape of the leads.

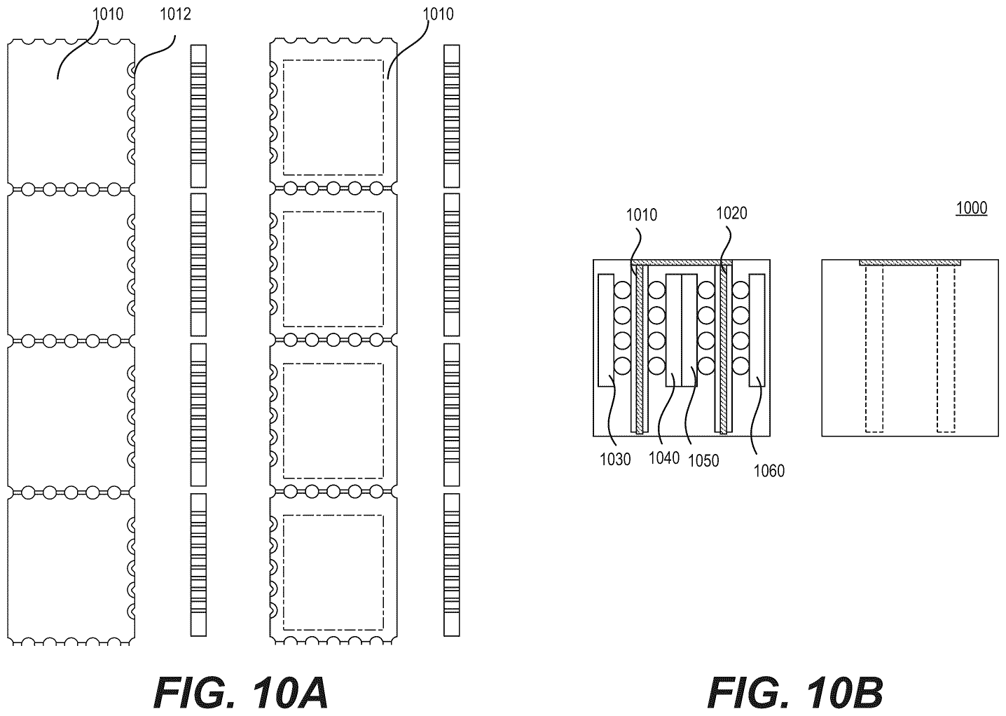

FIG. 10A and FIG. 10B are diagrams illustrating exemplary package assemblies using castellated edge plated leads, in accordance with some embodiments of the present disclosure. As shown in the top, bottom and different side views of the PCB(s) 1010 in FIG. 10A, castellations 1012 (or castellated edges, plated holes on the board's edge, plated half-holes, etc.) may be included along the edges of the PCB(s) 1010, which allow an electrical connection to another board through the side edges of the PCB(s) 1010. FIG. 10B illustrates the top and bottom views of an exemplary package assembly 1000 using the PCB(s) 1010, 1020 with castellations 1012 as the first and second boards in the stack structure to achieve the power module discussed in the above embodiments. As shown in FIG. 10B, charge pump assemblies 1030, 1040, 1050 and 1060 are mounted on corresponding surfaces of the double-sided PCB(s) 1010 and 1020.

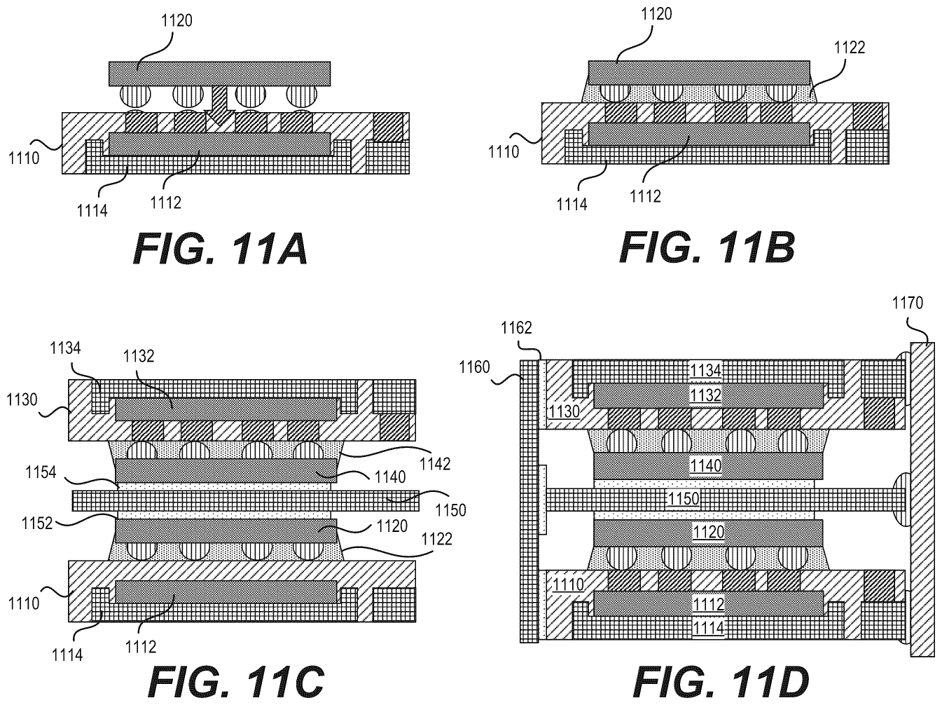

FIGS. 11A-11D are diagrams illustrating exemplary stages in an embedded die packaging to achieve the power module, in accordance with some embodiments of the present disclosure. In the embodiments of FIGS. 11A-11D, a P2 structure is provided. As shown in FIG. 11A, in the embedded die substrate 1110, a semiconductor die 1112 may be embedded within the PCB material and/or the lead frame during formation of the substrate 1110. The semiconductor die 1112 can be electrically connected to other components on or in the substrate through copper-plated vias and conductive traces of the substrate 1110. A heatsink structure 1114 may also embedded to achieve high thermal dissipation. As shown in FIG. 11A, another semiconductor die 1120 can be mounted on the embedded die substrate 1110. Then, as shown in FIG. 11B, an underfill material 1122 can be deposited in the gap between the die 1120 and the substrate 1110 to obtain one stack unit.

As shown in FIG. 11C, in another embedded die substrate 1130, a semiconductor die 1132 may be embedded within the PCB material and/or the lead frame during formation of the substrate 1130. The semiconductor die 1132 can be electrically connected to other components on or in the substrate through copper-plated vias and conductive traces of the substrate 1130. A heatsink structure 1134 may also be embedded to achieve high thermal dissipation. A semiconductor die 1140 can be mounted on the embedded die substrate 1130, with an underfill material 1142 deposited in the gap between the die 1140 and the substrate 1130 to obtain another stack unit. The semiconductor die 1120 and the semiconductor die 1140 can be attached to opposite surfaces of a heatsink structure 1150 via thermal interface material (TIM) 1152, 1154. As shown in FIG. 11D, the heatsink structure 1160 can be mounted to the embedded die substrates 1110, 1130 and the heatsink structure 1150 via TIM(s) 1162, and the embedded die substrates 1110, 1130 can be mounted to a carrier board 1170, to form the power module.

FIGS. 11E-11G are diagrams illustrating exemplary stages in an embedded die packaging to achieve the power module, in accordance with some other embodiments of the present disclosure. In the embodiments of FIGS. 11E-11G, a P3 structure is provided. As shown in FIG. 11E, in a P3 structure, two semiconductor dies 1182 and 1184 may be embedded within the PCB material and/or the lead frame during formation of the embedded die substrate 1180. The semiconductor dies 1182 and 1184 may be attached to opposite surfaces of a heatsink structure 1186 embedded in the substrate 1180 to achieve high thermal dissipation. Two semiconductor dies 1192 and 1194 can be mounted on opposite surfaces of the embedded die substrate 1180 and respectively coupled to the embedded semiconductor dies 1182 and 1184. Similarly, underfill materials can be deposited in the gap between the semiconductor dies 1192 and 1194 and the substrate 1180.

As shown in FIG. 11F, the semiconductor die 1192 and the semiconductor die 1194 can be respectively attached to heatsink structures 1156 and 1158 via thermal interface material (TIM) 1188a, 1188b. Then, as shown in FIG. 11G, the heatsink structure 1196 can be mounted to the embedded die substrate 1180 and the heatsink structures 1156, 1158 via TIM(s). The carrier board 1170 may also be mounted to the embedded die substrate 1180 and the heatsink structures 1156 and 1158 to form the power module. It would be appreciated that the operations and structures discussed above in the embodiments of FIGS. 11A-11G are simplified examples for the ease of understanding, and not meant to limit the present disclosure.

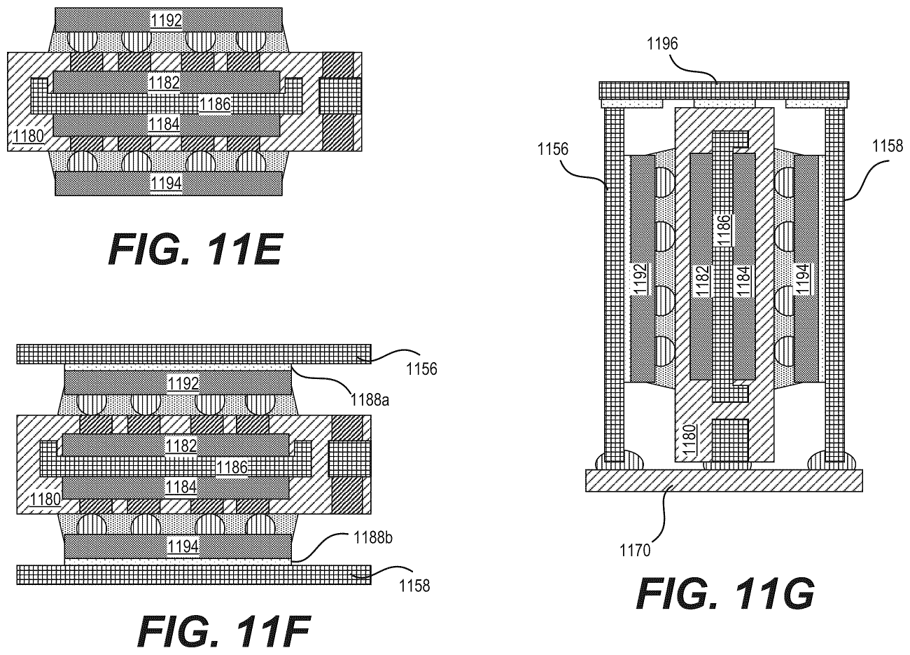

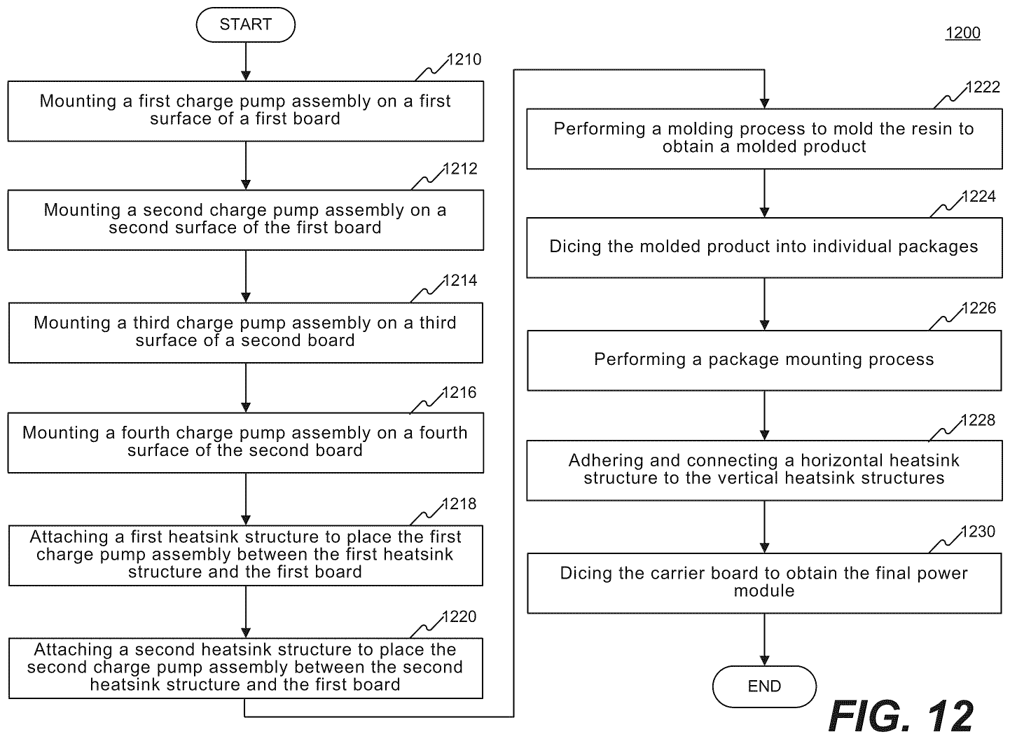

FIG. 12 is a flowchart of a method 1200 for assembling a power module, in accordance with some embodiments of the present disclosure. It is understood that additional operations may be performed before, during, and/or after the method 1200 depicted in FIG. 12, and that some other processes may only be briefly described herein. The method 1200 can be performed to assemble a power module with charge pump devices with increased power density, e.g., any of the power modules illustrated in the embodiments of FIG. 1-FIG. 11G above, but the present disclosure is not limited thereto. FIG. 13-FIG. 20 are diagrams illustrating exemplary stages in the method 1200 of FIG. 12 for assembling the power module, in accordance with some embodiments of the present disclosure. The method 1200 includes operations 1210-1230.

In operation 1210, a first charge pump assembly may be mounted on a first surface of a first board. The first charge pump assembly may include a first power conversion circuit configured to convert an input voltage to an output voltage. As shown in FIG. 13, in some embodiments, IC(s) 1310 forming the first power conversion circuit and terminal block(s) 1320 of the first charge pump assembly may be mounted on the first surface 1332 of the first board 1330.

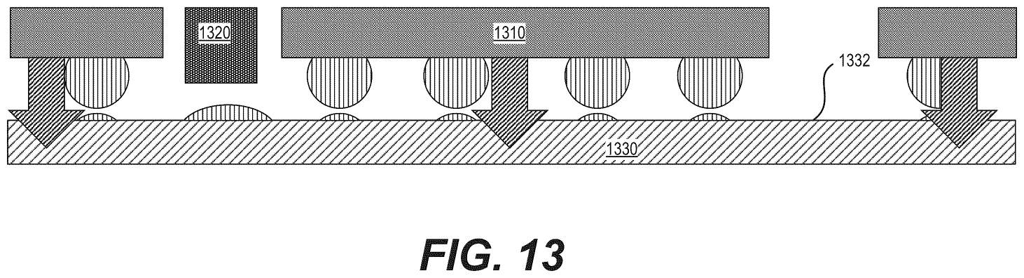

In operation 1212, a second charge pump assembly may be mounted on a second surface of the first board. The second charge pump assembly may include a second power conversion circuit configured to convert the input voltage to the output voltage, and the first surface and the second surface are opposite to each other. As shown in FIG. 14, the first board 1330 may be a double-sided sub-board, and IC(s) 1410 forming the second power conversion circuit and terminal block(s) 1420 of the second charge pump assembly are mounted at corresponding positions on the second surface 1334 of the first board 1330.

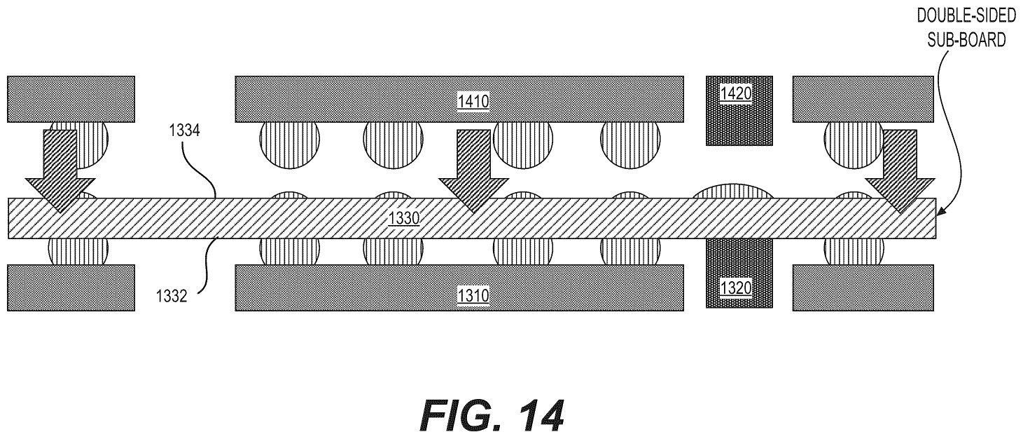

In operation 1214, a third charge pump assembly may be mounted on a third surface of a second board. In operation 1216, a fourth charge pump assembly may be mounted on a fourth surface of the second board. Similar to the first and the second charge pump assemblies in the operations 1210 and 1212 above, the third charge pump assembly may include a corresponding third power conversion circuit configured to convert the input voltage to the output voltage. The fourth charge pump assembly may include a fourth power conversion circuit configured to convert the input voltage to the output voltage, and the third surface and the fourth surface are opposite to each other. As shown in FIG. 15, in some embodiments, IC(s) 1315 forming the third power conversion circuit and terminal block(s) 1325 of the third charge pump assembly may be mounted on one surface of the second board 1340, and IC(s) 1415 forming the fourth power conversion circuit and terminal block(s) 1425 of the fourth charge pump assembly may be mounted on the opposite surface of the second board 1340. The mounting processes are similar to those for the first and the second charge pump assemblies as shown in FIG. 13 and FIG. 14, and thus the detailed discussion is not repeated herein.

In operation 1218, a first heatsink structure may be attached to place the first charge pump assembly between the first heatsink structure and the first board. In operation 1220, a second heatsink structure may be attached to place the second charge pump assembly between the second heatsink structure and the first board. For example, as shown in FIG. 15, the first and the second heatsink structures 1510, 1520 may be adhered to respective charge pump assemblies. In the embodiments of FIG. 15, the second heatsink structure 1520 may also be attached to place the third charge pump assembly between the second heatsink structure 1520 and the second board 1340, and a third heatsink structure 1530 may be attached to place the fourth charge pump assembly between the third heatsink structure 1530 and the second board 1340. In FIG. 15, thermal interface material (TIM) 1540 can be applied between the heat source surfaces (e.g., IC(s) 1310, 1410, 1315, and 1415) and the heatsink structures (e.g., heatsink structures 1510, 1520, and 1530) to efficiently dissipate heat from the heat source.

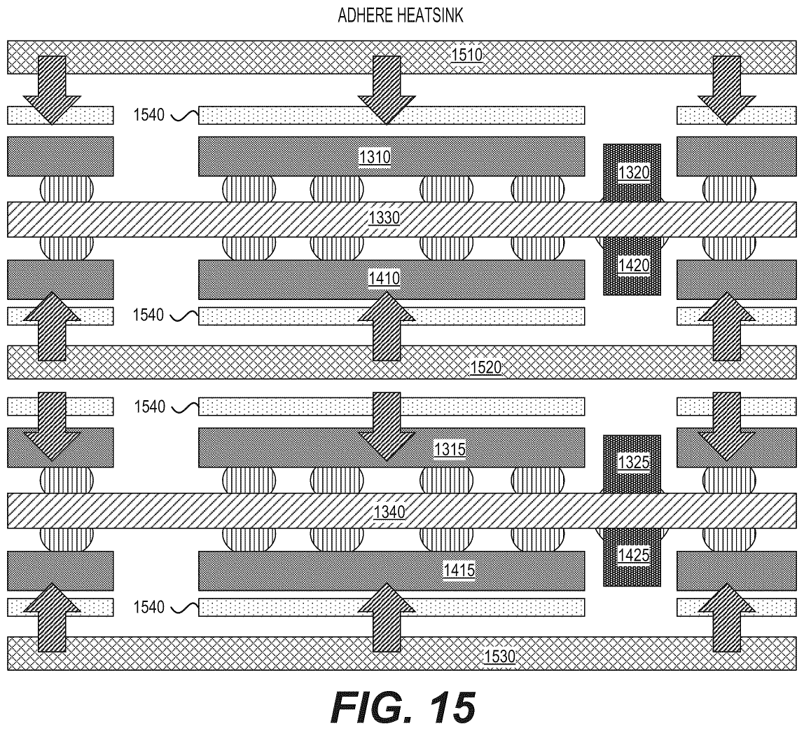

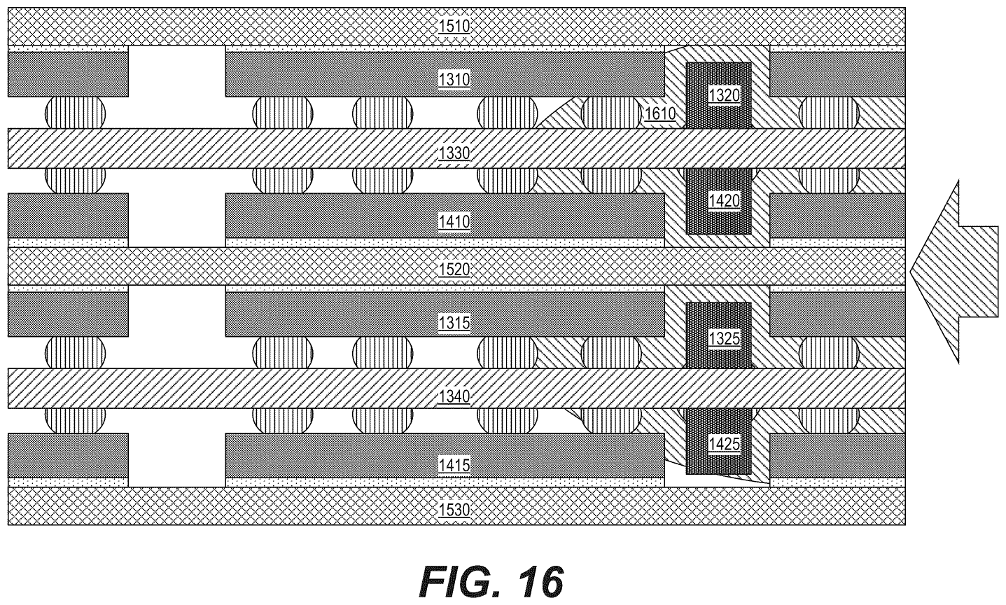

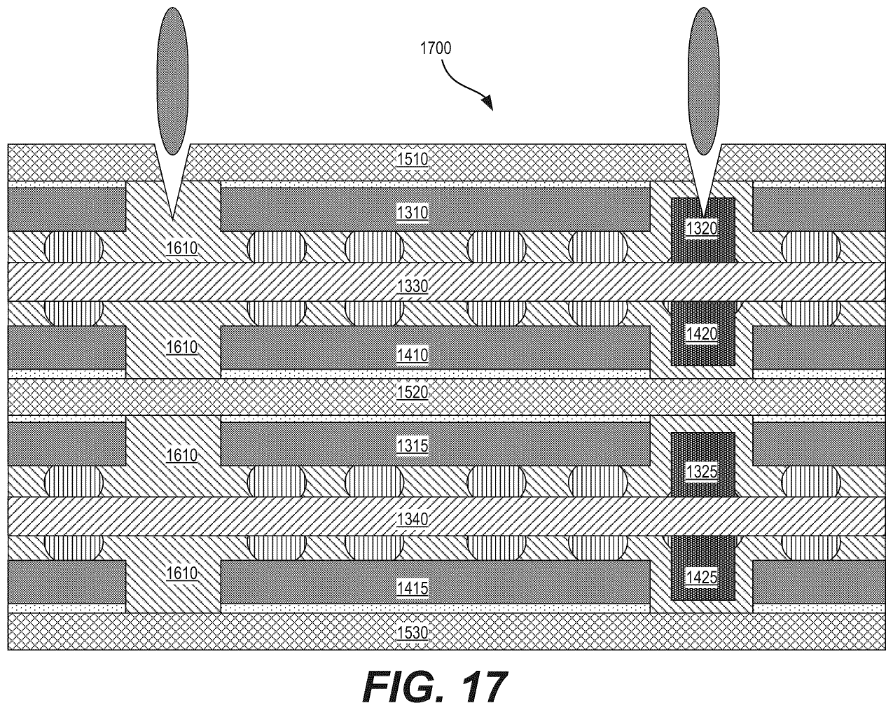

As shown in FIG. 16, in operation 1222, a molding process may be performed to mold the resin 1610 to obtain a molded product. Then, as shown in FIG. 17, in operation 1224, the molded product 1700 may be diced into individual packages having the charge pump circuits. As shown in FIG. 18, in the package mounting process of the operation 1226, the obtained module 1810 may be mounted to the carrier board 1820. Specifically, the first board 1330 may be mounted on the carrier board 1820 of the power module, and the first surface may be positioned to be perpendicular to the bottom surface of the carrier board 1820. The second board 1340 may also be mounted on the carrier board 1820, and the third surface may be perpendicular to the bottom surface of the carrier board 1820. In various embodiments, the first board 1330 and the second board 1320 may also be mounted on the carrier board 1820 by using a land grid array or a ball grid array, or by using a leadframe structure.

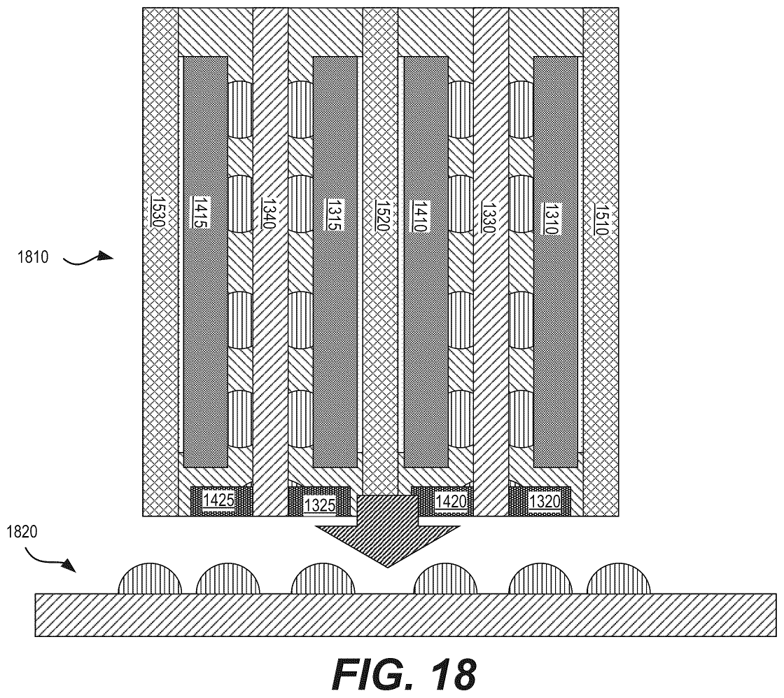

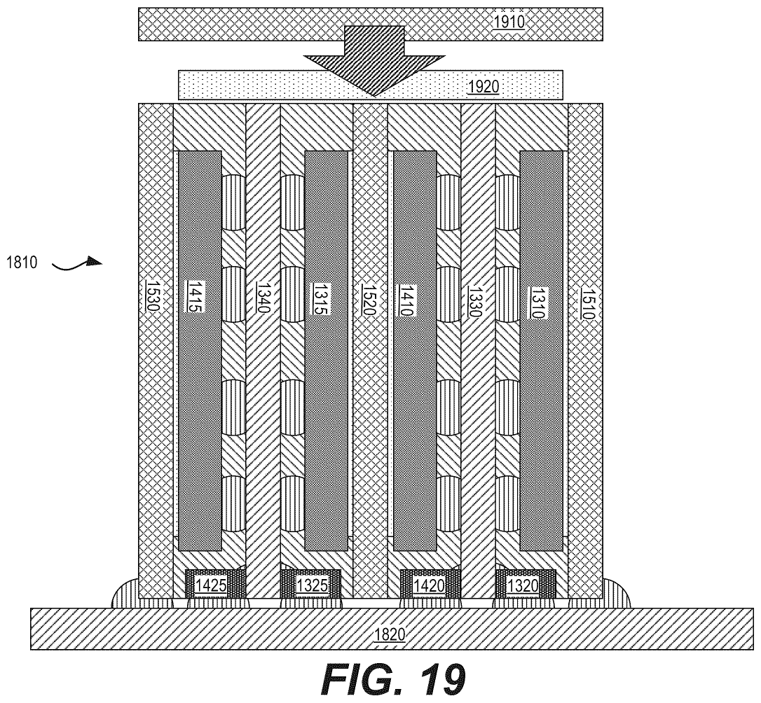

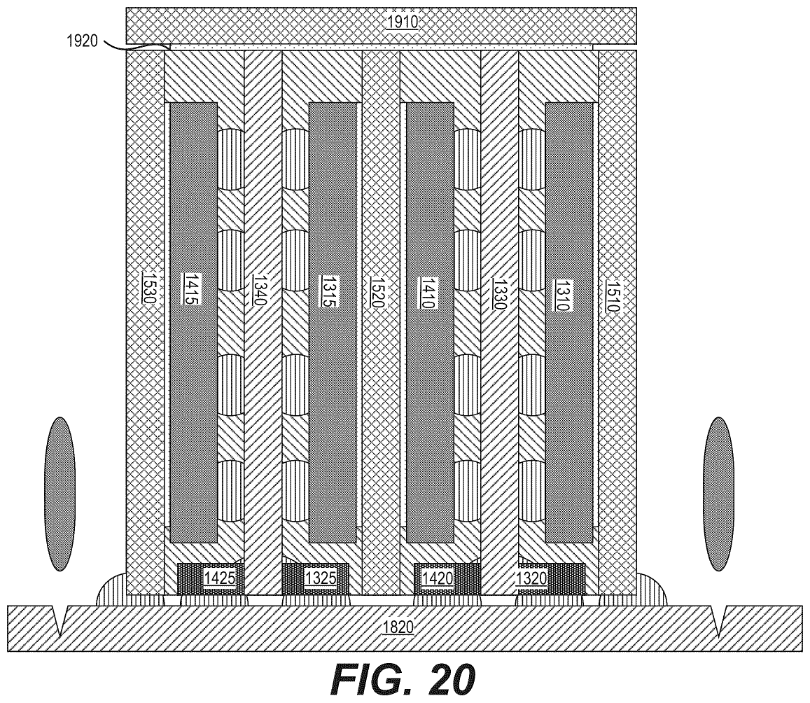

As shown in FIG. 19, in the operation 1228, a horizontal heatsink structure 1910 may be adhered and connected to the vertical heatsink structures 1510, 1520, and 1530. Similarly, thermal interface material (TIM) 1920 can be applied between the horizontal heatsink structure 1910 and the module 1810 including heatsink structures 1510, 1520, and 1530 to efficiently dissipate heat from the heat source. Finally, in the operation 1230, as shown in FIG. 20, the carrier board 1820 may be diced to obtain the final power module. FIG. 21 is a diagram illustrating an exemplary power module 2100 as the final product, in accordance with some embodiments of the present disclosure.

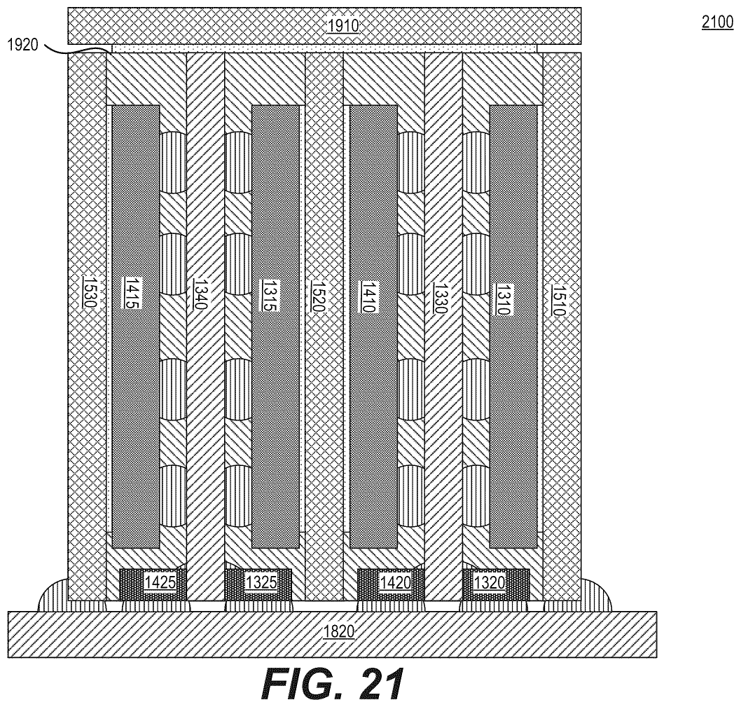

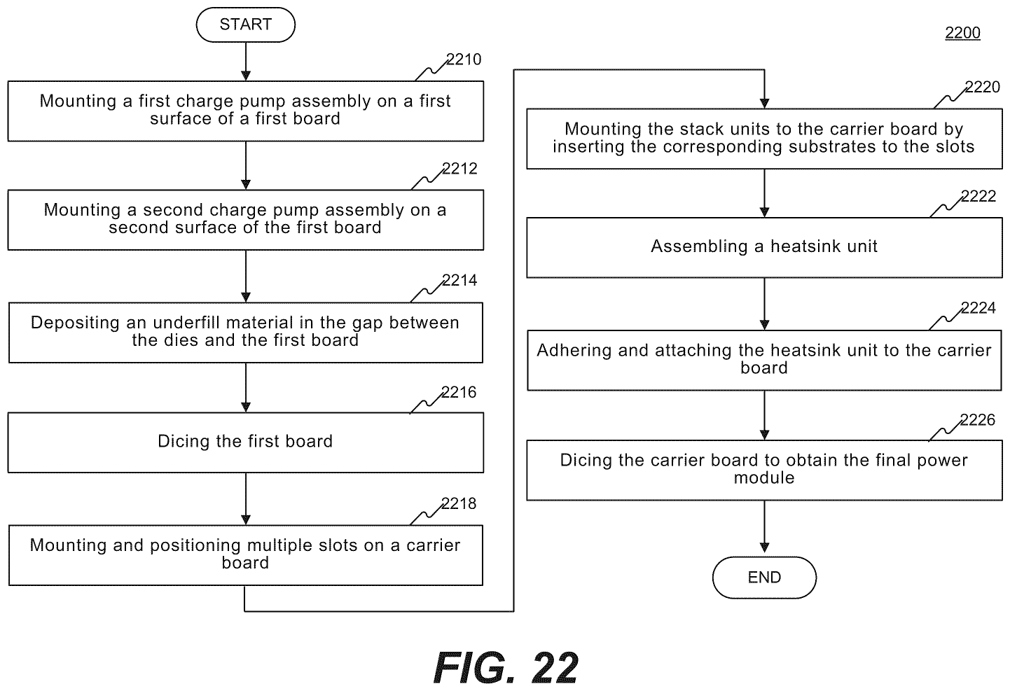

FIG. 22 is a flowchart of an alternative method 2200 for assembling a power module, in accordance with some embodiments of the present disclosure. Similar to the method 1200 in FIG. 12, additional operations may be performed before, during, and/or after the method 2200 depicted in FIG. 22, and that some other processes may only be briefly described herein. The method 2200 can also be performed to assemble a power module with charge pump devices with increased power density, e.g., any of power modules illustrated in the embodiments of FIG. 1-FIG. 11G above, but the present disclosure is not limited thereto. FIG. 23-FIG. 31 are diagrams illustrating exemplary stages in the method 2200 of FIG. 22 for assembling the power module, in accordance with some embodiments of the present disclosure. The method 2200 includes operations 2210-2226.

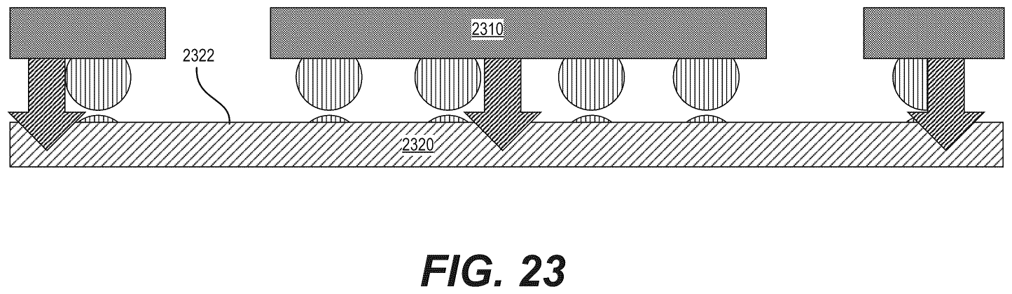

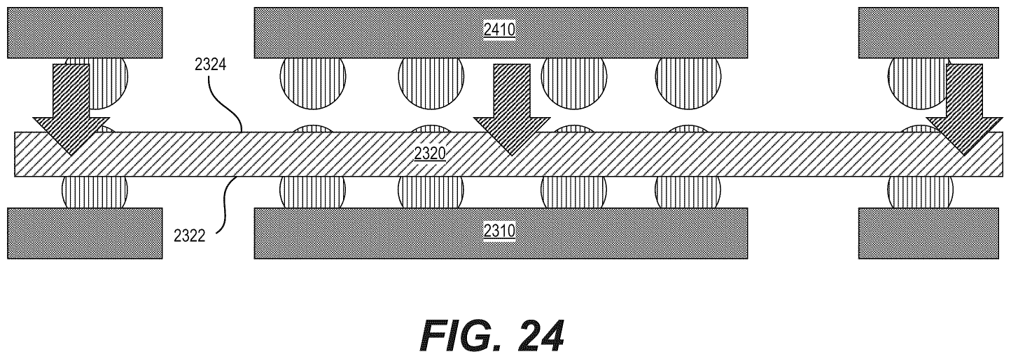

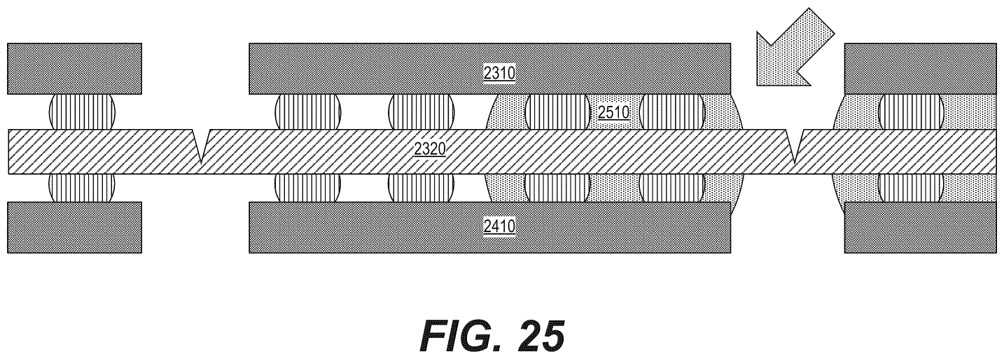

In operations 2210 and 2212, as respectively shown in FIG. 23 and FIG. 24, similar to the operations 1210 and 1220 in the method 1200, the first charge pump assembly (e.g., the die(s) 2310) may be mounted on the first surface 2322 of the first board 2320, and the second charge pump assembly (e.g., the die(s) 2410) may be mounted on the second surface 2324 at the opposite side of the first board 2320. In operation 2214, as shown in FIG. 25, an underfill material 2510 may be deposited in the gap between the dies 2310 and 2410 and the first board 2320. In operation 2216, as shown in FIG. 26, the first board 2320 may be diced to obtain one or more stack units having charge pump assemblies mounted on both sides of the substrate.

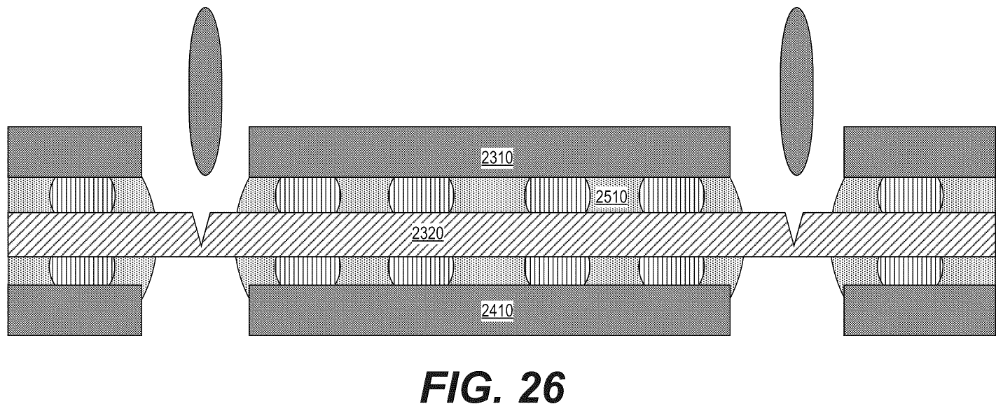

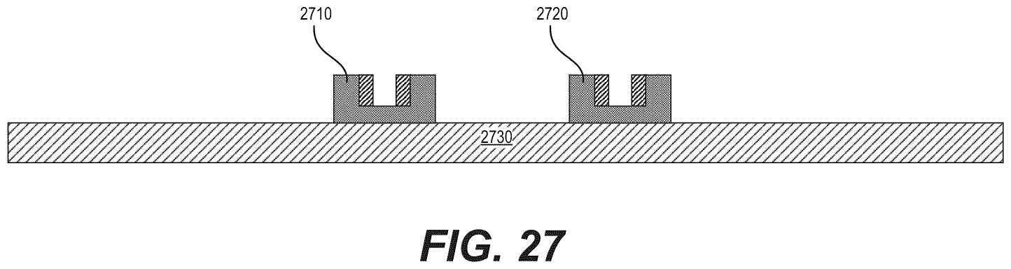

In operation 2218, as shown in FIG. 27, multiple slots 2710 and 2720 may be mounted and positioned at proper positions on a carrier board 2730. Then, in operation 2220, as shown in FIG. 28, the stack units 2810 and 2820 may be mounted to the carrier board 2730 by inserting the corresponding substrates 2812 and 2822 to the slots 2710 and 2720 on the carrier board 2730.

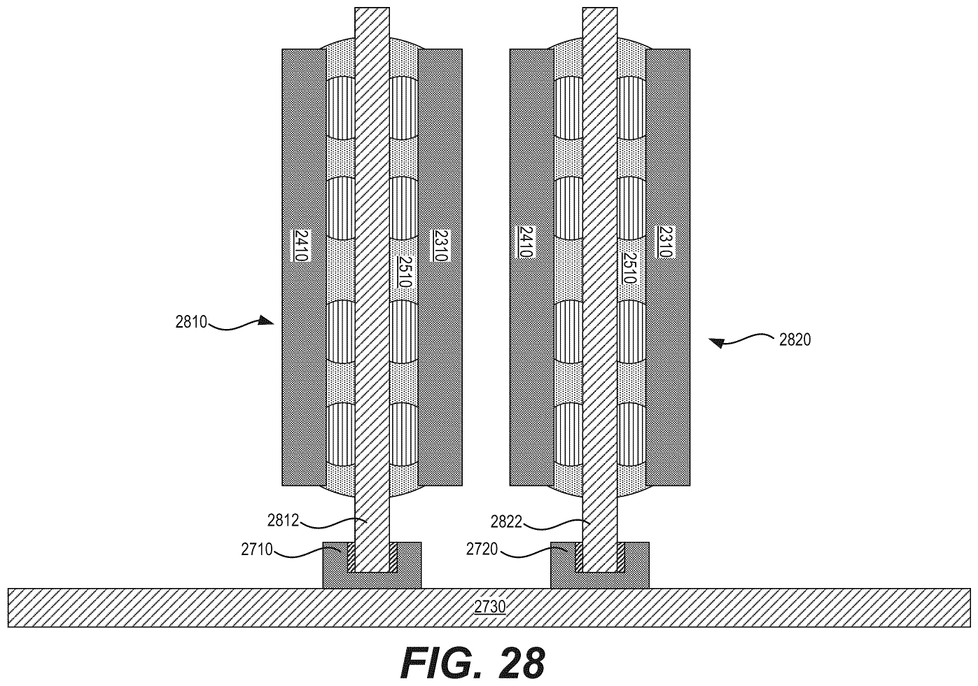

In operation 2222, as shown in FIG. 29, a heatsink unit 2910 may be assembled. The heatsink unit 2910 may include vertical heatsink structures 2912, 2914, and 2916 parallel to each other, and a horizontal heatsink structure 2918 connecting the vertical heatsink structures 2912, 2914, and 2916. In FIG. 29, thermal interface material (TIM) 2920 can be applied between the horizontal heatsink structure 2918 and the vertical heatsink structure 2914.

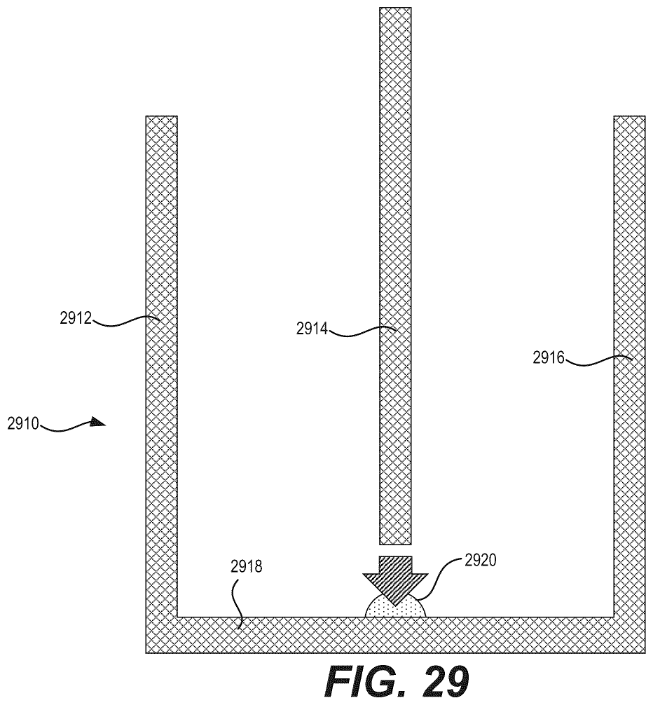

In operation 2224, as shown in FIG. 30, the heatsink unit 2910 may be adhered and attached to the carrier board 2730 to place the first board (e.g., substrate 2812) between the first heatsink structure 2912 and the second heatsink structure 2914, and to place the second board (e.g., substrate 2822) between the second heatsink structure 2914 and the third heatsink structure 2916. In FIG. 30, thermal interface material (TIM) 3010 can be applied between the stack units 2810 and 2820 and the heatsink unit 2910, and between the heatsink unit 2910 and the carrier board 2730.

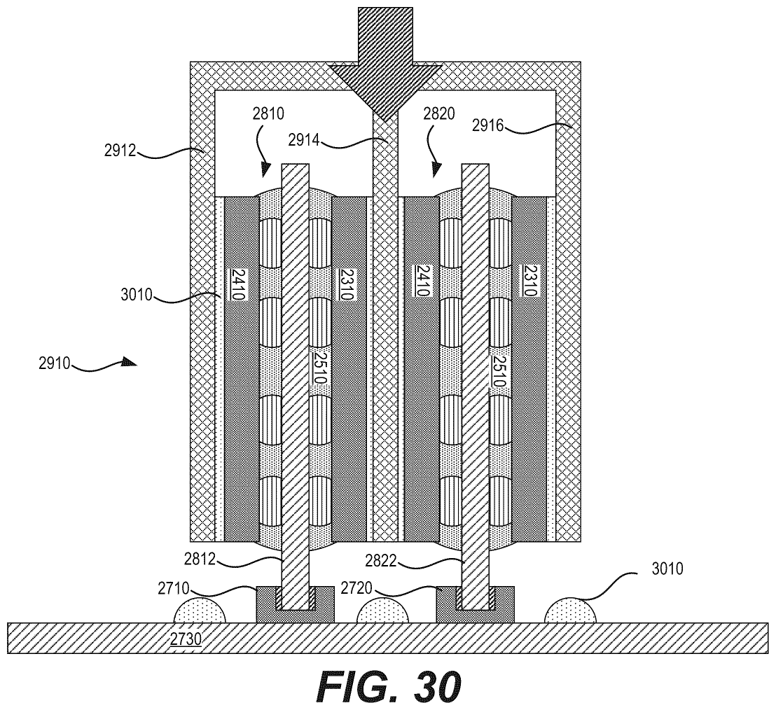

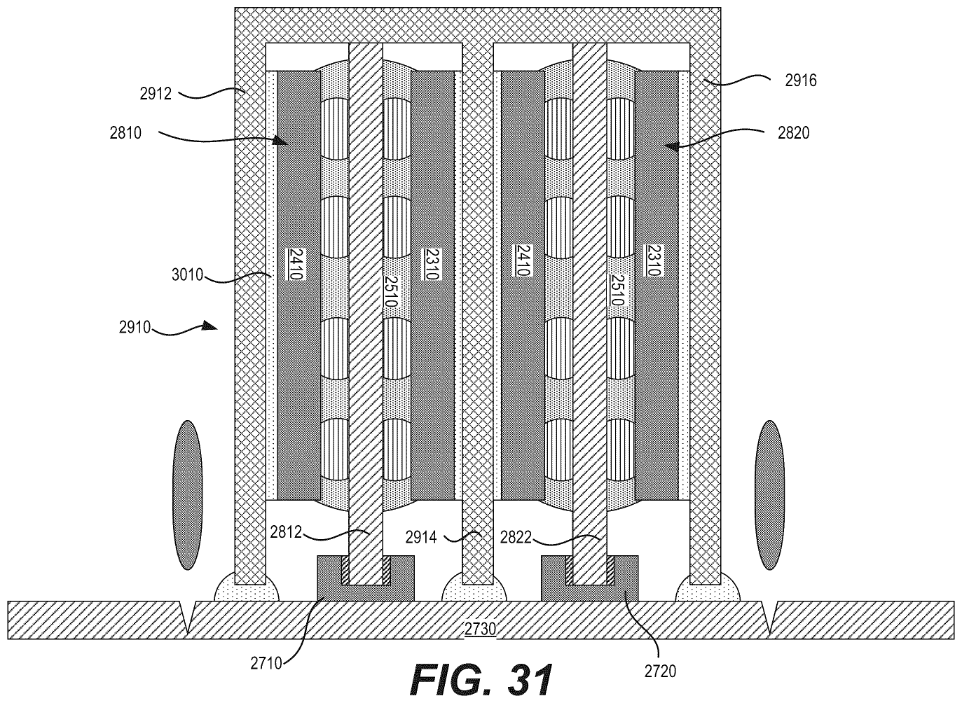

In operation 2226, as shown in FIG. 31, the carrier board 2730 may be diced to obtain the final power module. FIG. 32 is a diagram illustrating an exemplary power module 3200 as the final product, in accordance with some embodiments of the present disclosure.

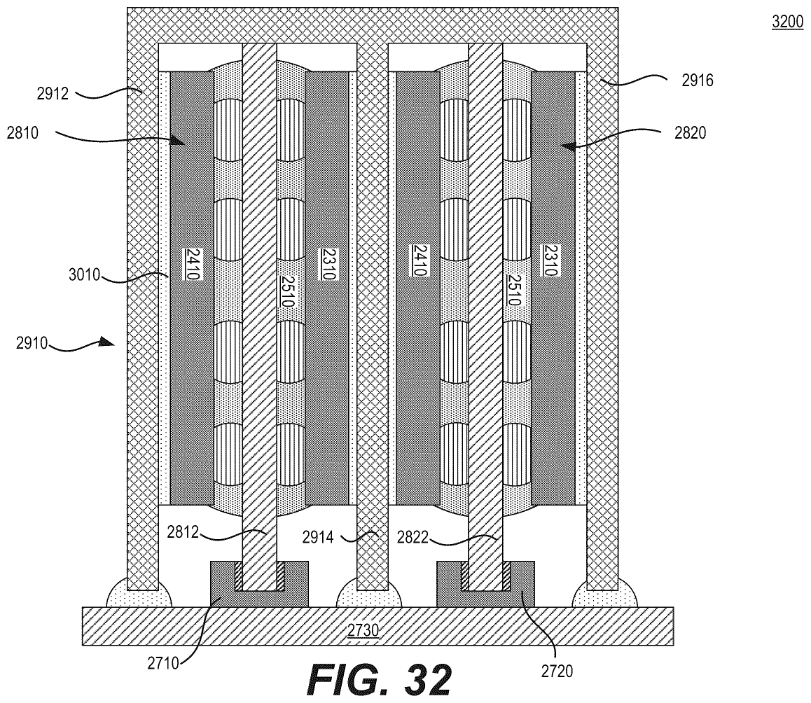

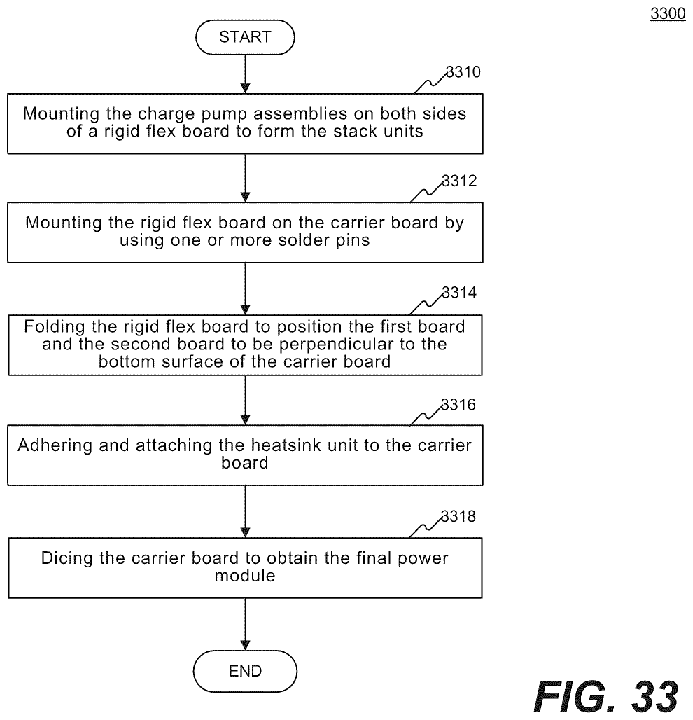

FIG. 33 is a flowchart of an alternative method 3300 for assembling a power module, in accordance with some embodiments of the present disclosure. Similar to the method 1200 in FIG. 12, additional operations may be performed before, during, and/or after the method 3300 depicted in FIG. 33, and that some other processes may only be briefly described herein. The method 3300 can also be performed to assemble a power module with charge pump devices with increased power density, e.g., any of power modules illustrated in the embodiments of FIG. 1-FIG. 11G above, but the present disclosure is not limited thereto. FIG. 34-FIG. 41 are diagrams illustrating exemplary stages in the method 3300 of FIG. 33 for assembling the power module, in accordance with some embodiments of the present disclosure.

The method 3300 includes operations 3310-3318. In operations 3310, as shown in FIG. 34, the charge pump assemblies may be mounted on both sides of a rigid flex board (e.g., a rigid flex PCB) to form the stack units 3402 and 3404. Specifically, the first charge pump assembly (e.g., the die(s) 3412) may be mounted on the first surface 3422 of the first board 3420, and the second charge pump assembly (e.g., the die(s) 3414) may be mounted on the second surface 3424 at the opposite side of the first board 3420 to form the stack unit 3402. The third charge pump assembly (e.g., the die(s) 3432) may be mounted on a third surface 3442 of a second board 3440, and a fourth charge pump assembly (e.g., the die(s) 3434) may be mounted on a fourth surface 3444 of the second board 3440 to form the stack unit 3404. In the embodiments FIG. 34, the first board 3420 and the second board 3440 may be rigid PCB sections of a rigid flex board 3450, and connected via a flexible section of the rigid flex board 3450. Alternatively stated, the first board 3420 and the second board 3440 may be connected with the rigid flex board 3450.

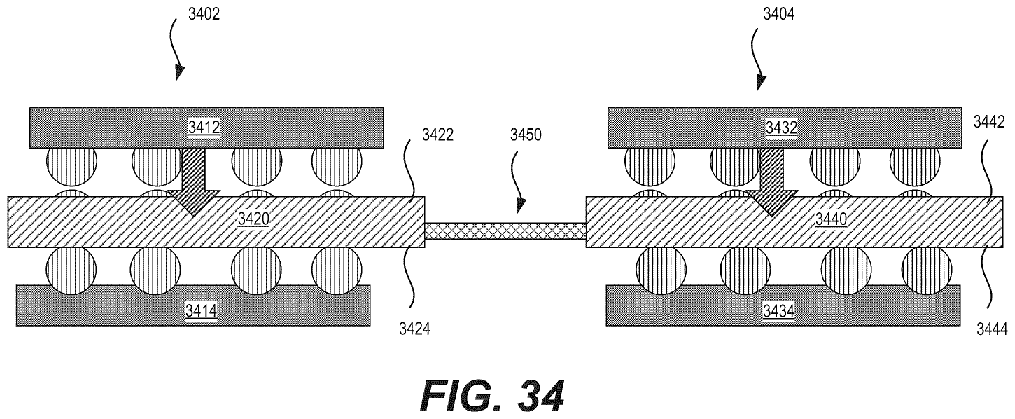

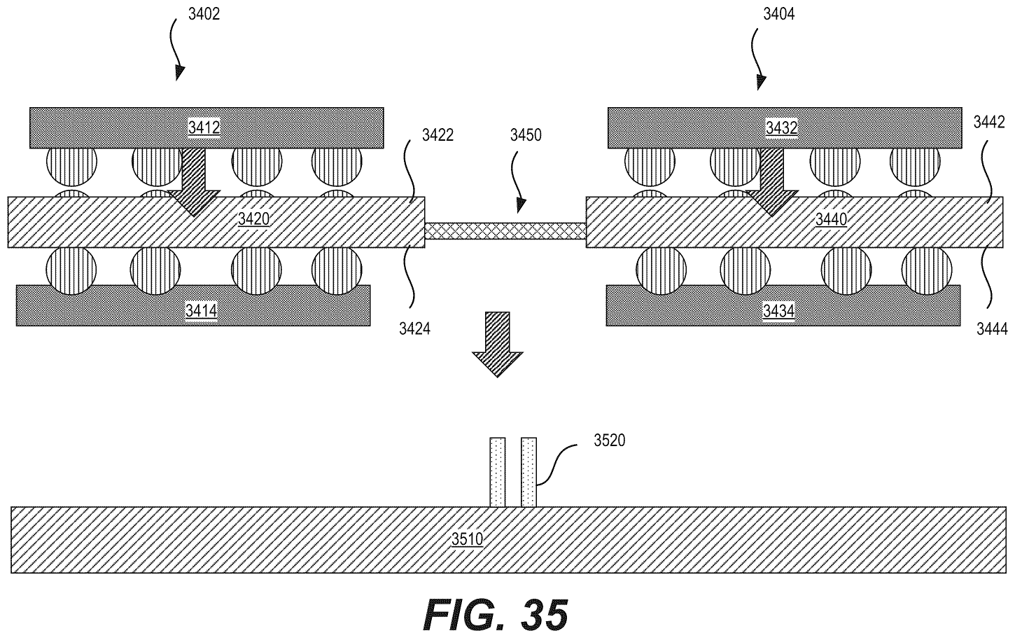

In operations 3312, as shown in FIG. 35, the rigid flex board 3450 may be mounted on the carrier board 3510 by using one or more solder pins 3520. For example, the solder pins 3520 may be micro miniature solder pins, but the present disclosure is not limited thereto. In operations 3314, as shown in FIG. 36, the rigid flex board 3450 may be folded to position the first board 3420 and the second board 3440 to be perpendicular to the bottom surface of the carrier board 3510.

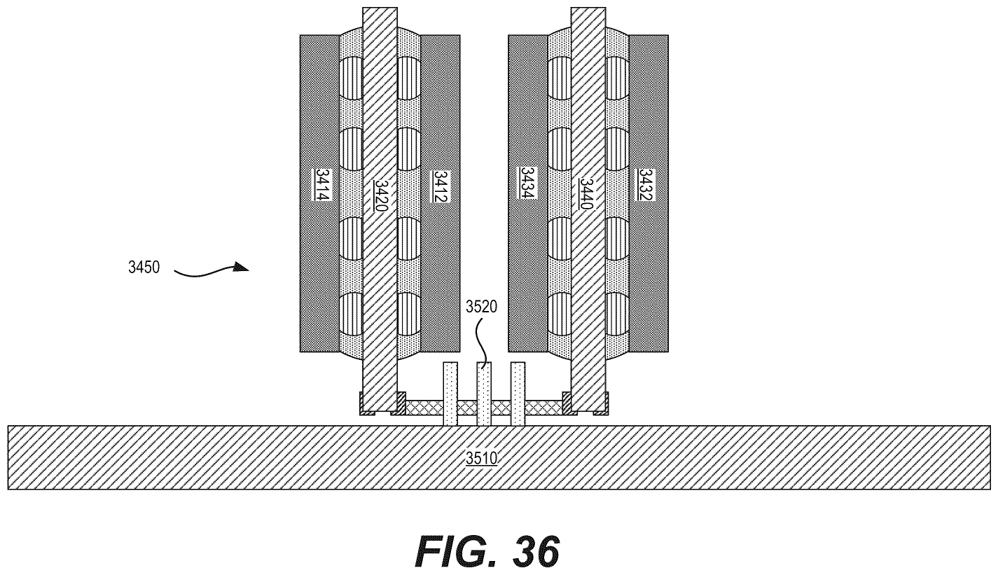

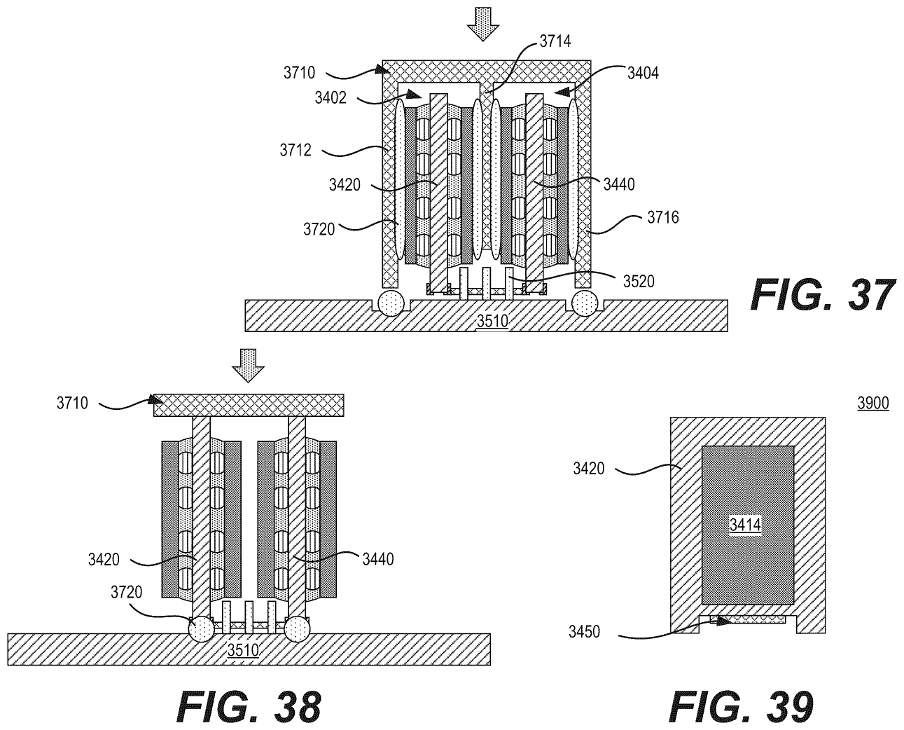

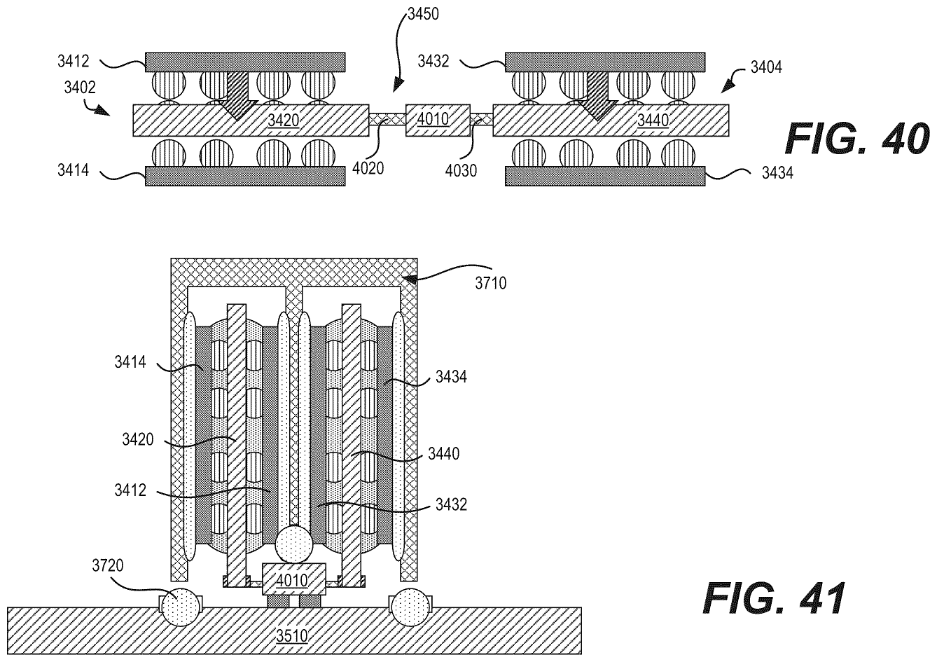

In operations 3316, as shown in FIG. 37, the heatsink unit 3710 may be adhered and attached to the carrier board 3510 to place the first board 3420 between the first heatsink structure 3712 and the second heatsink structure 3714, and to place the second board 3440 between the second heatsink structure 3714 and the third heatsink structure 3716. In FIG. 37, thermal interface material (TIM) 3720 can be applied between the heatsink unit 3710 and the stack units 3402, 3404, and the heatsink unit 3710 may be bonded in place in grooves or retainers in the carrier board 3510. Then, in operation 3318, the carrier board 3510 can be diced to obtain the final power module. In some other embodiments, as shown in FIG. 38, thermal planes can also be used in the device PCBs to conduct heat away from the heat generating component and bonded in place in slots in the carrier board 3510. FIG. 39 shows a side view of an exemplary power module 3900 using the thermal plane for heat dissipation.

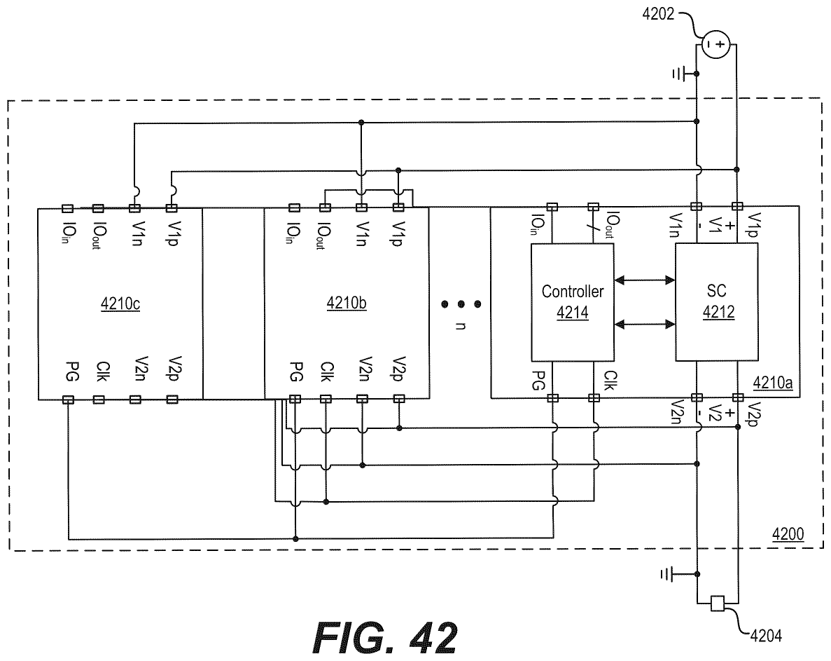

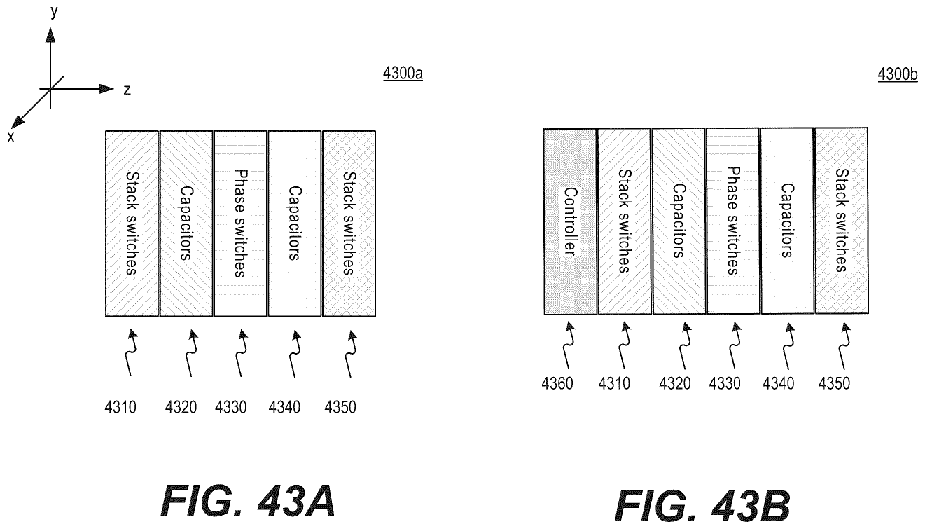

In some other embodiments, the rigid flex board may also be a rigid flex board with a middle interconnect, in which a middle part of the rigid flex board is replaced with a substrate. As shown in FIG. 40 and FIG. 41, compared to the embodiments of FIG. 34-FIG. 39, the rigid flex board 3450 in FIG. 40 and FIG. 41 may further include a middle rigid section 4010, which is connected to the stack units 3402 and 3404 via respective flexible sections 4020 and 4030 of the rigid flex board 3450. As shown in FIG. 40, the components and dies may be first attached to the rigid flex board 3450 in horizontal. As shown in FIG. 41, the rigid flex board 3450 may then be folded and mounted on the carrier board 3510 by attaching the middle rigid section 4010 to the carrier board 3510, positioning the first board 3420 and the second board 3440 to be perpendicular to the bottom surface of the carrier board 3510, and attaching the heatsink unit 3710 to the carrier board 3510. Detailed operations for assembling the power module shown in FIG. 40 and FIG. 41 are similar to those discussed with respect to the embodiments of FIG. 34-FIG. 39, and thus are not repeated herein.

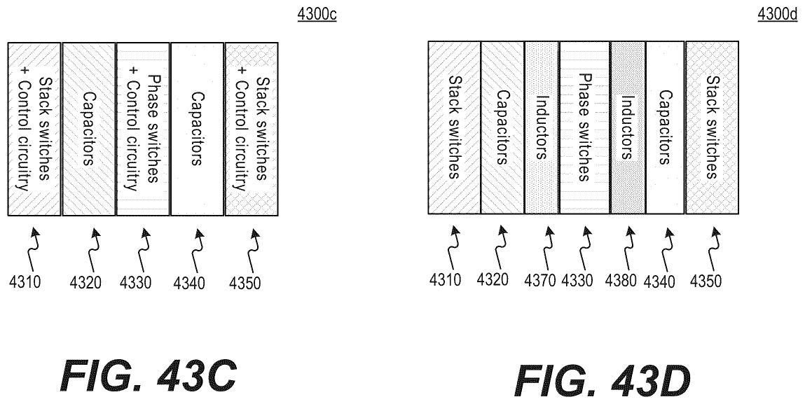

FIG. 42 is a diagram illustrating an exemplary power converter 4200, in accordance with some embodiments of the present disclosure. As shown in FIG. 42, the power converter 4200 may include multiple circuit assemblies 4210a, 4210b, and 4210c coupled to each other, which provide a plurality of charge pump circuits coupled in parallel and configured to convert an input voltage V1 to an output voltage V2. The power converter 4200 may be formed by the structure of the power module(s) discussed in various embodiments above, where a bottom surface is provided for mounting the power module to a circuit board, and circuit assemblies 4210a, 4210b, and 4210c are stacked along a first direction parallel to the bottom surface. In some embodiments, one power module may include one or more of the circuit assemblies 4210a, 4210b, and 4210c. It is noted that the number of the circuit assemblies 4210a, 4210b, and 4210c may vary in different embodiments, and FIG. 42 is a simplified example and not meant to limit the present disclosure.

The circuit assembly 4210a may include a switched capacitor circuit 4212 (also known as a charge pump circuit) and a controller circuit 4214 configured to control the operation of the switched capacitor circuit 4212. Specifically, the controller circuit 4214 may include control circuitry, timing circuitry, protection circuitry, and gate drivers, among other components, configured to operate the switches, which in turn may change the electrical configuration of the switched capacitor circuit 4212 between a first mode/state or second mode/state.

In the embodiments of FIG. 42, the power converter 4200 may be configured to receive energy from a voltage source 4202 at an input voltage V1 between input terminals V1p and Vin respectively and deliver that energy to an output load 4204 with an output voltage V2 between output terminals V2p and V2n respectively. In some embodiments, the input voltage V1 may be higher than the output voltage V2. The circuit assemblies 4210a, 4210b, and 4210c each may include a power converting circuit (e.g., switched capacitor circuit 4212) configured to convert the input voltage V1 to the output voltage V2. As shown in the embodiments of FIG. 42, by using multiple power modules (e.g., including multiple circuit assemblies 4210a, 4210b, and 4210c) with input terminals V1p and Vin of the switched capacitor circuits connected together and output terminals V2p and V2n of the switched capacitor circuits connected together in the power converter 4200, the power converter 4200 may achieve higher power rating based on low-cost and low-rating devices. Accordingly, the modular design also offers the flexibility and scalability of the power converting circuits to meet different needs in power supply systems in various applications.

In some embodiments, the circuit assemblies 4210a, 4210b, and 4210c may respectively include corresponding switched capacitor circuit 4212 and individual controller circuit 4214, but the present disclosure is not limited thereto. In some embodiments, switched capacitor circuits 4212 in the circuit assemblies 4210a, 4210b, and 4210c may be controlled by an external master controller coupled to the circuit assemblies 4210a, 4210b, and 4210c. In some other embodiments, the power converter 4200 may include one internal master controller (e.g., controller circuit 4214 in the circuit assembly 4210a), and one or more slave controllers (e.g., controller circuit 4214 in the circuit assemblies 4210b and 4210c) configured to communicate with the internal master controller. In addition, one or more of the power modules in the power converter 4200 may support Power Management Bus (PMBUS) Communications protocol, while remaining power modules are “light” power modules having a simpler design without PMBUS and/or telemetry circuits.

In some embodiments, the controller circuit 4214 may be fabricated on a semiconductor substrate such as silicon, gallium nitride (GaN), Silicon-On-Insulator (SOI), Silicon-On-Sapphire (SOS), Silicon-On-Glass (SOG), Silicon-On-Quartz (SOQ), among other substrates, using semiconductor processing techniques compatible with complementary metal oxide semiconductor (CMOS) fabrication. The controller circuit 4214 may be physically integrated with the switches in the switched capacitor circuit 4212 on the same substrate (e.g., an on-chip configuration) or as an off-chip component configured to operate the switches in the switched capacitor circuit 4212.

As shown in FIG. 42, in some embodiments, input terminals V1p, Vin and output terminals V2p, V2n of the switched capacitor circuit 4212 in each circuit assembly 4210a, 4210b, and 4210c may be coupled. In addition, some input terminals of the controller circuit 4214, such as a PG terminal for receiving a “Power Good” (PG) signal or a CLK terminal for receiving a clock signal, may also be coupled in parallel, such that the circuit assemblies 4210a, 4210b, and 4210c may receive the same PG signal and the same clock signal. Some other terminals, such as I/O pins IOin and IOout of the circuit assemblies 4210a, 4210b, and 4210c, may be coupled in series to facilitate the circuit operations. In the present disclosure, the terms “node” and “terminal” may be used interchangeably.

In various embodiments of the present disclosures, the circuit assemblies 4210a, 4210b, and 4210c including charge pump circuits can be stacked horizontal and mounted vertically in a package to provide high power density for the power converter 4200. In other words, the circuit assemblies 4210a, 4210b, and 4210c can be provided in a power module with a bottom surface of a carrier board for mounting the power module to a circuit board and providing electrical connections. The circuit assemblies 4210a, 4210b, and 4210c may be stacked along a first direction parallel to the bottom surface of the carrier board.

Accordingly, the circuit assemblies 4210a, 4210b, and 4210c may form a power conversion circuit including a plurality of switched capacitor circuits 4212 coupled in parallel to convert a first voltage (e.g., input voltage V1) to a second voltage (e.g., output voltage V2).

As previously discussed in the embodiments of FIG. 4, the switched capacitor circuit 4212 may include a plurality of fly capacitors (e.g., capacitors 440 and 450 in FIG. 4), a plurality of stack switches (e.g., stack switches 410 and 420 in FIG. 4) coupled to positive terminals of the plurality of fly capacitors via a plurality of dc nodes, and a plurality of phase switches (e.g., phase switches 430 in FIG. 4) coupled to negative terminals of the plurality of fly capacitors via a first phase node or a second phase node of the switched capacitor circuit. The switched capacitor circuit 4212 is configured to transition between different states in response to switching of the plurality of stack switches and the plurality of phase switches to convert the first voltage to the second voltage.

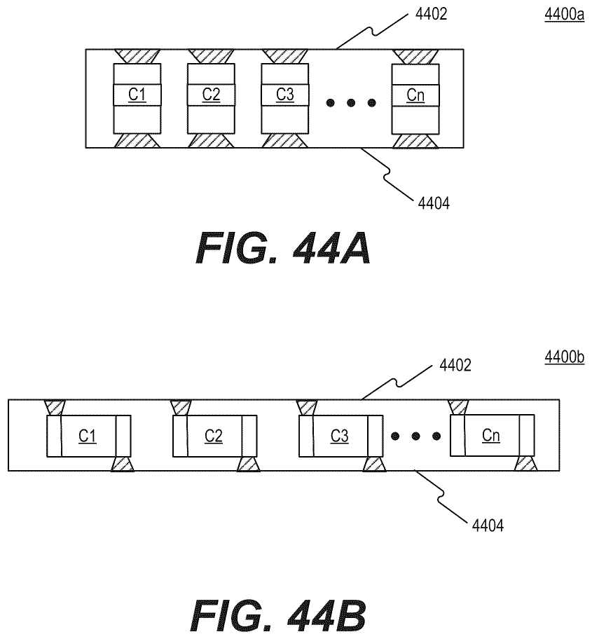

In various embodiments, the components within in the switched capacitor circuit 4212 can also be arranged in a stacked structure. FIG. 43A is a diagram illustrating an exemplary structure 4300a, in accordance with some embodiments of the present disclosure. The structure 4300a may be used to implement the switched capacitor circuit 4212. As shown in FIG. 43A, multiple layers 4310-4350 are stacked, e.g., along a z-direction perpendicular to a substrate. Particularly, the structure 4300a includes active device layers 4310, 4330, and 4350, and passive device layers 4320 and 4340. A stacked configuration may include a stack of alternating active device layers 4310, 4330, and 4350 and passive device layers 4320 and 4340, but the present disclosure is not limited thereto.

In some embodiments, active device layers 4310, 4330, and 4350 may include switching elements (e.g., switches 410, 420, and 430 of FIG. 4) fabricated on a semiconductor substrate such as, but not limited to, bulk silicon, doped silicon, GaN, GaAs, or SOI. The stack switches 410 and 420, and the phase switches 430 may be implemented by field-effect transistors, bipolar junction transistors, diodes, or other electrical devices. In some embodiments, one or more of the active device layers 4310, 4330, and 4350 may further include control circuitry (e.g., controller circuit 4214 of FIG. 42) fabricated on the same semiconductor substrate as the switching elements such that controller circuit 4214 is physically integrated with the switches. In some embodiments, passive device layers 4320 and 4340 may include passive devices including capacitors (e.g., capacitors 440 and 450 of FIG. 4) or resistors fabricated on a substrate. The substrate may include, but is not limited to, glass, quartz, silicon, SOI, SOS, SOG, SOQ, ceramic (alumina, aluminum-nitride, sapphire), or composite, among other substrate materials.

In the structure 4300a, the passive device layer 4320 is disposed between the active device layer 4310 and the active device layer 4330. Specifically, the passive device layer 4320 is stacked above the active device layer 4310, which may be a bottom layer. The active device layer 4330 is stacked above the passive device layer 4320. In some embodiments, the active device layer 4310 includes first switches (e.g., stack switches 410 in FIG. 4 associated with the first phase). The passive device layer 4320 may include the first capacitors (e.g., capacitors 440 in FIG. 4 associated with the first phase). The active device layer 4330 may include second switches (e.g., phase switches shared by the first and the second phases). By providing conductive features (e.g., contacts), the stack switches in the active device layer 4310 and the phase switches in the active device layer 4330 can be interconnected with the first capacitors in the passive device layer 4320 to form the switched capacitor circuit (e.g., the charge pump circuit) for the first phase. As previously explained in the embodiments above, the switched capacitor circuit transitions between at least two states in response to the switching of the stack switches and the phase switches. In some embodiments, the first and second capacitors may be multi-layer ceramic capacitors.

Similarly, the passive device layer 4340 is disposed between the active device layer 4330 and the active device layer 4350 to form the switched capacitor circuit for the second phase. Thus, the phase switches in the active device layer 4330 can be shared by two phases and interconnected with the capacitors in different passive device layers 4320 and 4340. Specifically, the passive device layer 4340 is stacked above the active device layer 4330, and the active device layer 4350, which may be a top layer, is stacked above the passive device layer 4340. As used herein, a “bottom” layer is the layer closest to a substrate providing an electrical interface and a “top” layer is the layer furthest from the substrate.

The active device layer 4350 may include third switches (e.g., stack switches associated with the second phase). The passive device layer 4340 may include second capacitors (e.g., capacitors associated with the second phase). By providing conductive features (e.g., contacts), the stack switches in the active device layer 4350 and the phase switches in the active device layer 4330 can be interconnected with the capacitors in the passive device layer 4340 to form the switched capacitor circuit for the second phase.

Accordingly, the structure 4300a may form a multi-phase switched capacitor circuit (e.g., the two-phase switched capacitor circuit), which transitions between at least two states in response to switching of the stack switches and the phase switches arranged in different active device layers. In the present embodiments, the first switches in a bottom layer (e.g., active device layer 4310) may be stack switches associated with the first phase. The third switches in a top layer (e.g., active device layer 4350) may be stack switches associated with the second phase. The second switches in an intermediate layer (e.g., active device layer 4330) are phase switches for both the first phase and the second phase, to connect the first capacitors in one layer (e.g., passive device layer 4320) stacked below the intermediate layer and the second capacitors in another layer (e.g., passive device layer 4340) stacked above the intermediate layer to the shared phase nodes of the switched capacitor circuit. In some embodiments, the passive device layer 4320 may further include an inductor coupled with one or more of the first capacitors to form a resonant charge pump or a multi-level charge pump.

It is also noted that in other embodiments, the structure 4300a may have multiple passive device layers stacked on a single active device layer, or multiple active device layers stacked on a single passive device layer, or a stack including at least one of a passive device layer, an interconnect layer, and an active device layer. For example, the structure 4300a may additionally include an interconnect layer to provide an electrical connection between active device layers and passive device layers, or to provide an electrical connection between devices in active device layers through metal lines.

FIG. 43B is a diagram illustrating another exemplary structure 4300b, in accordance with some embodiments of the present disclosure. Compared to the embodiments of FIG. 43A, as shown in FIG. 43B, a controller layer 4360 including circuitry of the controller circuit 4214 may be disposed as a bottom layer, and the device layers 4310-4350 may be stacked above the controller layer 4360. The controller circuit 4214 in the controller layer 4360 may be coupled with switches in the device layers 4310, 4330, and 4350 through contacts and vias, so as to provide control signals to control the stack switches and the phase switches for each phase. Accordingly, the structure 4300b may be used to implement the circuit assembly 4210a shown in FIG. 42.

FIG. 43C is a diagram illustrating another exemplary structure 4300c, in accordance with some embodiments of the present disclosure. Compared to the embodiments of FIG. 43A and FIG. 43B, in the structure 4300c, the device layers 4310, 4330, and 4350 may respectively include corresponding control circuitry for controlling the switching of the stack switches or the phase switches in the same device layer. In some embodiments, control circuitry in these device layers 4310, 4330, and 4350 may communicate with each other through contacts and vias and collectively perform operations of the controller circuit 4214 to provide control signals for each phase. Accordingly, the structure 4300c may also be used to implement the circuit assembly 4210a shown in FIG. 42.

FIG. 43D is a diagram illustrating another exemplary structure 4300d, in accordance with some embodiments of the present disclosure. Compared to the embodiments of FIG. 43A-FIG. 43C, the structure 4300d further includes additional passive device layers 4370 and 4380. The passive device layers 4370 and 4380 may be inductor layers respectively including inductors. For example, the passive device layer 4370 may be stacked between the passive device layer 4320 and the active device layer 4330, such that inductors in the passive device layer 4370 are connected between corresponding capacitors in the passive device layer 4320 and the phase switches in the active device layer 4330. Alternatively stated, one or more of the circuit assemblies 4210a, 4210b, and 4210c may include an inductor layer adjacent to the first passive device layer 4320. The inductor layer may include an inductor coupled with one or more of the first capacitors in the first passive device layer 4320 to form a resonant charge pump or a multi-level charge pump.

Similarly, the passive device layer 4380 may be stacked between the passive device layer 4340 and the active device layer 4330, such that inductors in the passive device layer 4380 are connected between corresponding capacitors in the passive device layer 4340 and the phase switches in the active device layer 4330. Accordingly, the structure 4300d may also be used to implement the switched capacitor circuit including one or more inductors as energy storage elements, or a converter with an LC filter coupled with the switched capacitor network to promote adiabatic charging or discharging. It is noted that in other alternative embodiments, the passive device layer 4370 may be stacked between the passive device layer 4320 and the active device layer 4310, the passive device layer 4380 may be stacked between the passive device layer 4340 and the active device layer 4350. The structure 4300d in FIG. 43D is an example and not meant to limit the present disclosure.

In various embodiments, the passive device layers 4320 and 4340 may be implemented in different ways to provide vertical capacitors connecting between the phase switches and stack switches, which may reduce the routing distance and reduce the parasitic inductance in the circuit.

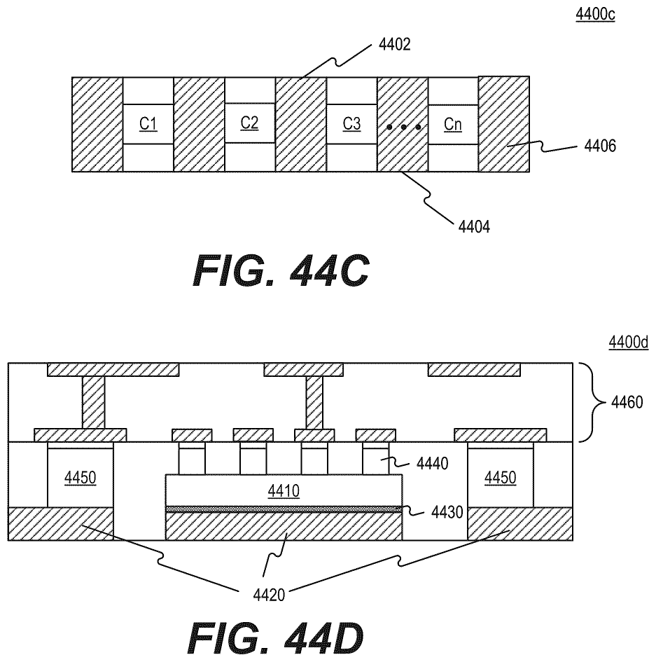

FIGS. 44A-44C are diagrams illustrating exemplary passive device layers 4400a, 4400b, and 4400c, in accordance with some embodiments of the present disclosure. In some embodiments, the capacitors C1, C2, C3 to Cn embedded in each passive device layer 4400a, 4400b, or 4400c may be multi-layer ceramic capacitors (MLCC). MLCCs may store electric energy in multiple ceramic layers having a high dielectric constant. For example, barium titanate (BaTi03) may be selected as the dielectric. In the structure of an MLCC, numerous metal electrodes and ceramic layers are alternately stacked within the capacitor. The internal electrodes are arranged in an interdigitated pattern with the adjacent electrodes extending to the opposing terminals, while the non-adjacent electrodes extend to the same terminal. On each terminal, a metalized coating applied to the exterior faces, called end termination, electrically connects the exposed electrode edges. MLCCs offer high capacitance, small size, low cost, high reliability, and excellent high-frequency characteristics and can be widely used in different applications.

As shown in FIG. 44A, in some embodiments, positive terminals of the capacitors C1, C2, C3 to Cn are coupled to corresponding contacts located on a first surface 4402 of the passive device layer 4400a, and negative terminals of the capacitors C1, C2, C3 to Cn are coupled to corresponding contacts located on a second surface 4404 of the passive device layer 4400a opposite the first surface 4402. The passive device layer 4400a is stacked with the layer having stack switches via the first surface 4402, and stacked with the layer having phase switches via the second surface 4404. Thus, the stack switches can be coupled to positive terminals of the capacitors C1, C2, C3 to Cn via dc nodes, and the phase switches can be coupled to negative terminals of the capacitors C1, C2, C3 to Cn via corresponding phase nodes. It would be appreciated that, in different arrangements, the stack switches can be stacked under or over the passive device layer 4400a, so the first surface 4402 may be either the top surface or the bottom surface. In the embodiments of FIG. 44A, the multi-layer ceramic capacitors C1, C2, C3 to Cn are embedded in the substrate, with the long edge of each multi-layer ceramic capacitor C1, C2, C3 to Cn being substantially perpendicular to the top surface or the bottom surface of the passive device layer 4400a, but the present disclosure is not limited thereto.

As shown in the passive device layer 4400b in FIG. 44B, the multi-layer ceramic capacitors C1, C2, C3 to Cn may also be embedded in the substrate with the long edge of each multi-layer ceramic capacitor C1, C2, C3 to Cn being substantially parallel to the top surface or the bottom surface of the passive device layer 4400b. Similar to the embodiments of FIG. 44A, positive terminals of the capacitors C1, C2, C3 to Cn are coupled to corresponding contacts located on the first surface 4402, while negative terminals of the capacitors C1, C2, C3 to Cn are coupled to corresponding contacts located on the second surface 4404 opposite the first surface 4402. As shown in the passive device layer 4400c in FIG. 44C, in some other embodiments, the multi-layer ceramic capacitors C1, C2, C3 to Cn may also be embedded vertically in molded compound material 4406, such as a molded plastic or other electrical insulator material, to form the passive device layer 4400c. It would be understood that the passive device layer may be realized by other approaches, and the embodiments illustrated in FIGS. 44A-44C are merely examples and not meant to limit the present disclosure.

In some embodiments, the active device layers 4310, 4330, and 4350 and/or the passive device layers 4320 and 4340 in the structure 4300a of FIG. 43A may also be formed using a molded interconnect substrate (MIS), and one or more of the stack switches, the phase switches, and the capacitors may be embedded with the molded interconnect substrate (MIS). Molded interconnect substrate is a packaging technology built on a lead frame substrate, which supports single-die or multi-die configurations.

FIG. 44D is a diagram illustrating an exemplary active device layer 4400d with the molded interconnect substrate, in accordance with some embodiments of the present disclosure. In the active device layer 4400d, one or more IC dies 4410 including active components (e.g., switches) is attached to a lead frame 4420, with a thermal interface material 4430 disposed between the IC dies 4410 and the lead frame 4420. Conductive pillars (e.g., Cu pillars) 4440 and 4450 are disposed to connect the IC die(s) 4410 or the lead frame 4420 to an MIS 4460 with a pre-molded structure. The MIS 4460 may include one or more layers pre-configured with copper plating or interconnects to provide electrical connections.

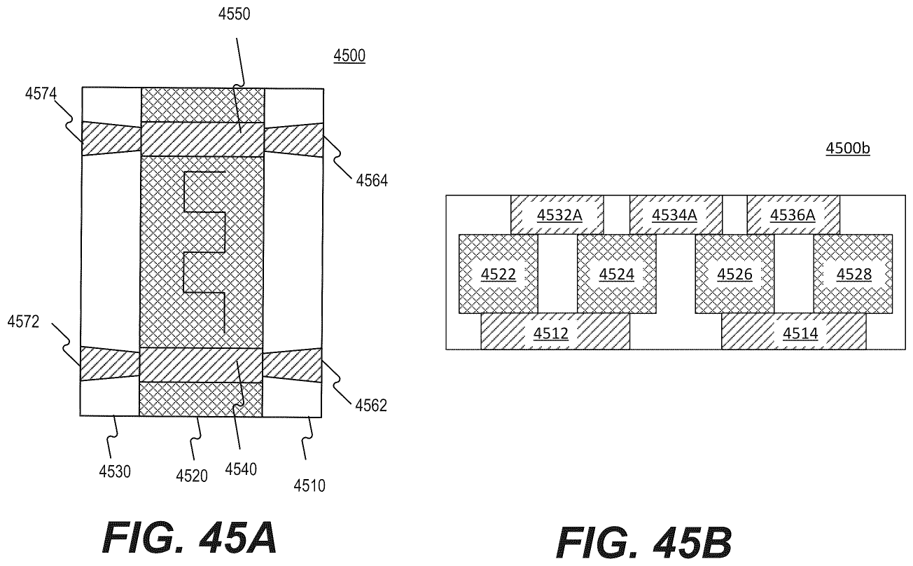

FIG. 45A is a diagram illustrating an exemplary structure 4500, in accordance with some embodiments of the present disclosure. The structure 4500 shown in FIG. 45A may be used to implement any of the circuit assemblies 4210a, 4210b, and 4210c. As shown in FIG. 45A, the structure 4500 is wafer-level stacked and includes a first active device layer 4510, a passive device layer 4520 stacked to the first active device layer 4510, and a second active device layer 4530 stacked to the passive device layer 4520. One or more through-vias 4540 and 4550 are formed and extend through the first active device layer 4510, the passive device layer 4520 and the second active device layer 4530.

In some embodiments, the first active device layer 4510 includes phase switches of the switched capacitor circuit, and the second active device layer 4530 includes stack switches of the switched capacitor circuit. The passive device layer 4520 between two active device layers 4510 and 4530 includes charge pump capacitors of the switched capacitor circuit. For example, the passive device layer 4520 may be a glass wafer/panel including the charge pump capacitors. In some embodiments, the structure 4500 provides bonding contacts 4562 and 4564 on one surface and bonding contacts 4572 and 4574 on another surface opposite the one surface for electrical connections to other devices stacked above or below the structure 4500. As shown in FIG. 45A, through-vias 4540 and 4550 may be configured to connect corresponding bonding contacts 4562 and 4564 and bonding contacts 4572 and 4574.

Reference is made to FIGS. 45B-45D for better understanding of the present disclosure. FIGS. 45B, 45C, and 45D are a side view 4500b, a bottom view 4500c, and a top view 4500d, respectively, of relative spatial arrangement of switches and capacitors formed in the structure 4500 of FIG. 45A, in accordance with some embodiments of the present disclosure. In the embodiments of FIGS. 45B-45D, stack switches 4532A-4536A and 4532B-4536B, phase switches 4512, 4514, 4516, and 4518, and capacitors 4522, 4524, 4526, and 4528 of a switched capacitor circuit can be formed in the layers in the structure 4500. Due to the region from which the cross-section has been selected, stack switches 4532B-4536B and phase switches 4516 and 4518 are not shown in FIG. 45B.

As shown in FIG. 45B, capacitors 4522, 4524, 4526, and 4528 may be arranged coplanar with each other and between stack switches 4532A-4536A and 4532B-4536B and phase switches 4512, 4514, 4516, and 4518. As shown in FIGS. 45B and 45C, capacitors 4522, 4524, 4526, and 4528 may be formed in a passive device layer (e.g., passive device layer 4520 of FIG. 45A), and phase switches 4512, 4514, 4516, and 4518 may be formed in a first switch layer (e.g., first active device layer 4510 of FIG. 45A). As shown in FIGS. 45B and 45D, stack switches 4532A-4536A and 4532B-4536B may be formed in a second switch layer (e.g., second active device layer 4530 of FIG. 45A).

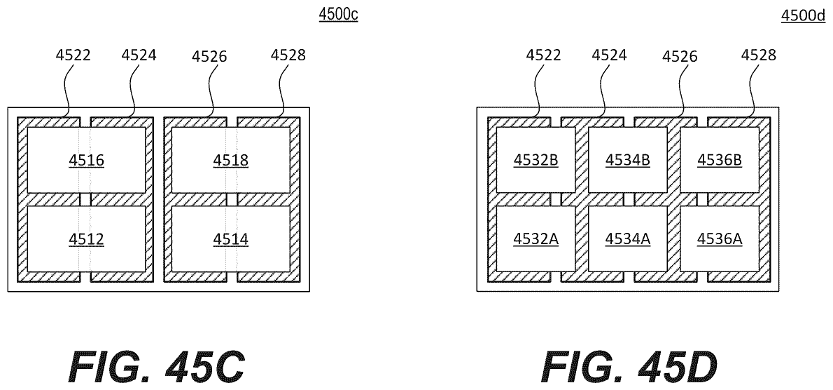

FIG. 46 is a diagram illustrating another exemplary structure 4600, in accordance with some embodiments of the present disclosure. The structure 4600 includes a substrate 4610 supporting capacitors C1A and C2A, and one or more dies 4620 (e.g., silicon dies), which collectively form a switched capacitor circuit. An encapsulant 4640 may be deposited over the capacitors C1A and C2A, and the one or more dies 4620 to encapsulate the switched capacitor circuit at least partially. Through-vias 4670 may extend through the encapsulant 4640 and be positioned in correspondence with bonding contacts 4660. For example, a compression molding process may be used to encapsulate the one or more dies 4620 and other components with a thermally conductive mold compound.

The substrate 4610 may be an FR-4 PCB or a patterned leadframe electrically coupled to bumps 4650 for routing power and signals. In various embodiments, the bumps 4650 may be solder bumps, copper pillars, copper stud bumps, golden stud bumps, etc., providing electrical communication between the structure 4600 and any external components. In some embodiments, the patterned leadframe is applied with a solder mask coating to avoid over-collapsing during the soldering process. The solder mask may be applied over leads, and formed with openings corresponding to conductive bumps 4650 respectively. Due to the region from which the cross-section has been selected, some capacitors in the structure 4600 may not be shown in FIG. 46.

As shown in FIG. 46, the capacitors C1A, C2A, and one or more dies 4620 can be mounted on the substrate 4610. Electrically conductive bumps 4622 are configured to provide electrical communication between the die(s) 4620 and the capacitors C1A, C2A. One or more heat spreaders 4630 may be disposed over the one or more dies 4620 to facilitate the heat transfer and dissipate the heat generated in the one or more dies 4620 during the operations. In some embodiments, the one or more dies 4620 may include a stack die containing stack switches and a phase die containing phase switches. In some other embodiments, stack switches and phase switches may be integrated in the same die. It would be appreciated that the die(s) 4620 may be arranged differently in various embodiments. For example, for the structure 4600 including multiple dies 4620, the dies 4620 may be arranged side-by-side with their respective device faces both facing the substrate 4610, or be arranged such that one die is stacked on top of another die.

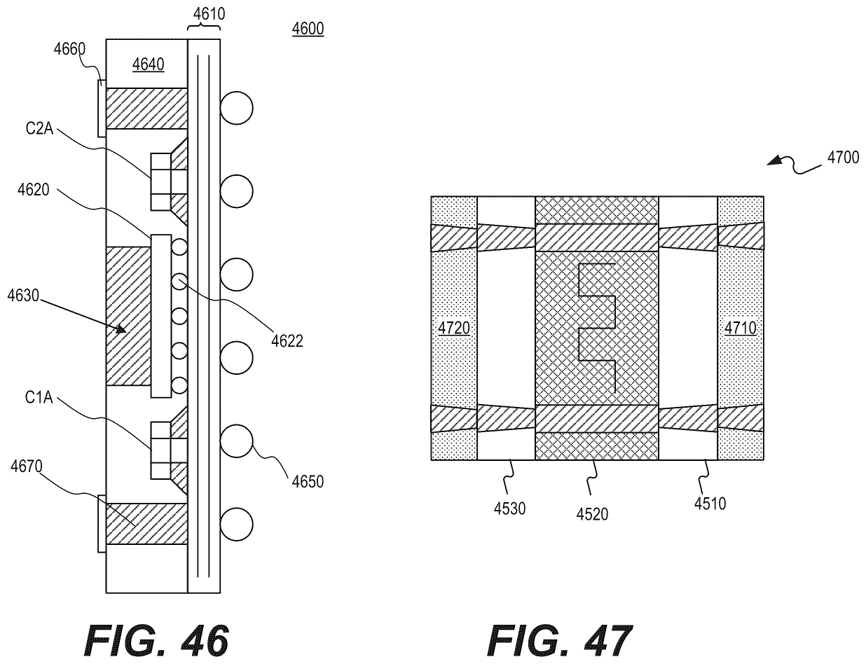

In some embodiments, the stacking dies and associated passive components often generate significant heat and result in thermal hotspots due to high-power devices within the packages. To facilitate heat dissipation, the power converter package may further include one or more heat spreader layers within a single switched-capacitor layer, or between two adjacent switched-capacitor layers. FIG. 47 is a diagram illustrating another exemplary structure 4700 including heat spreader layers, in accordance with some embodiments of the present disclosure. The structure 4700 may also be used to implement any of the circuit assemblies 4210a, 4210b, and 4210c. Like the structure 4500 of FIG. 45A, wafer-level stacking technology is applied in the structure 4700.

In addition to the first active device layer 4510, the passive device layer 4520, and the second active device layer 4530 stacked on one another, the structure 4700 may further include one or more heat spreader layers 4710 and 4720. The heat spreader layer 4710 may be arranged on one side of the structure 4700, adjacent to the first active device layer 4510. The heat spreader layer 4720 may be arrange on another side of the structure 4700, adjacent to the second active device layer 4530. Heat spreader layers 4710 and 4720 respectively may include a thermally conductive insulating material (e.g., SiC, AlN, diamond, etc.) for heat dissipation. Accordingly, heat spreader layers 4710 and 4720 may contribute to transferring the accumulated heat out of the stacked layers and avoid damages or performance degradation due to heat accumulation in the active device layers 4510 and 4530 or the passive device layer 4520.

In summary, the vertically-mounted and horizontally-stacked power modules and the methods for assembling the power modules disclosed in the present disclosure can be applied to manufacture power converters and power supply units for computer devices with improved heat dissipation properties for high-power output applications. In addition, the package can be scalable by adding layers in the structure, or scalable by increasing the number of boards included in a single package to increase the output power.

In the foregoing specification, embodiments have been described with reference to numerous specific details that can vary from implementation to implementation. Certain adaptations and modifications of the described embodiments can be made. It is also intended that the sequence of steps shown in figures is only for illustrative purposes and is not intended to be limited to any particular sequence of steps. As such, those skilled in the art can appreciate that these steps may be performed in a different order while implementing the same method.

The various example embodiments herein are described in the general context of method steps or processes, which may be implemented in one aspect by a computer program product, embodied in a transitory or a non-transitory computer-readable medium. For example, a non-transitory computer-readable storage medium may store a set of instructions that are executable by one or more processors of a device to cause the device to perform a method for designing a frame structure for stacking circuit assemblies. A computer-readable medium may include removable and nonremovable storage devices including, but not limited to, Read Only Memory (ROM), Random Access Memory (RAM), compact discs (CDs), digital versatile discs (DVD), etc.

It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable sub-combination or as suitable in any other described embodiment of the specification. Certain features described in the context of various embodiments are not to be considered essential features of those embodiments unless the embodiment is inoperative without those elements.

The embodiments may further be described using the following clauses:
1. A power module, comprising:
a first board comprising a first surface and a second surface opposite to each other and perpendicular to a bottom surface of the power module for mounting the power module to a circuit board, the bottom surface providing electrical connections to the circuit board;
a first charge pump assembly mounted on the first surface, the first charge pump assembly comprising a first power conversion circuit configured to convert an input voltage to an output voltage; and
a first vertical heatsink structure arranged adjacent to the first charge pump assembly, the first charge pump assembly being placed between the first vertical heatsink structure and the first board.
2. The power module of clause 1, further comprising:
a second charge pump assembly mounted on the second surface, the second charge pump assembly comprising a second power conversion circuit configured to convert the input voltage to the output voltage; and
a second vertical heatsink structure arranged adjacent to the second charge pump assembly, the second charge pump assembly being placed between the second vertical heatsink structure and the first board,
wherein the first and the second power conversion circuits are electrically coupled to each other in parallel.
3. The power module of clause 2, further comprising:
a second board arranged parallel to the first board, the second board comprising a third surface and a fourth surface opposite to each other and perpendicular to the bottom surface;
a third charge pump assembly mounted on the third surface, the third charge pump assembly comprising a third power conversion circuit configured to convert the input voltage to the output voltage;
wherein the second vertical heatsink structure is arranged between the second charge pump assembly and the third charge pump assembly.
4. The power module of clause 3, further comprising:
a fourth charge pump assembly mounted on the fourth surface, the fourth charge pump assembly comprising a fourth power conversion circuit configured to convert the input voltage to the output voltage; and
a third vertical heatsink structure arranged adjacent to the fourth charge pump assembly, the fourth charge pump assembly being placed between the third vertical heatsink structure and the second board,
wherein the third and the fourth power conversion circuits are electrically coupled in parallel to the first and the second power conversion circuits.
5. The power module of clause 3 or clause 4, further comprising:
a horizontal heatsink structure connected to the first vertical heatsink structure, the second vertical heatsink structure, and the third vertical heatsink structure.
6. The power module of any of clauses 1-5, wherein the first charge pump assembly comprises:
a first integrated circuit mounted on the first surface, the first integrated circuit comprising a plurality of stack switches of the first power conversion circuit;
a second integrated circuit mounted on the first surface and electrically connected to the first integrated circuit via a bus bar, the second integrated circuit comprising a plurality of phase switches of the first power conversion circuit; and
a plurality of fly capacitors of the first power conversion circuit coupled between the first integrated circuit and the second integrated circuit.
7. The power module of clause 6, wherein a distance of the first integrated circuit to the bottom surface is greater than a distance of the second integrated circuit to the bottom surface.
8. The power module of clause 6 or clause 7, wherein the first integrated circuit further comprises a controller configured to control the stack switches and the phase switches.
9. The power module of any of clauses 6-8, further comprising:
a controller mounted on the second surface and configured to control the stack switches and the phase switches.
10. The power module of any of clauses 1-9, wherein the first board comprises a printed circuit board (PCB) laminate structure, and the first charge pump assembly comprises one or more dies and capacitors mounted on the PCB laminate structure.
11. The power module of clause 10, wherein the first charge pump assembly further comprises one or more heat spreader layers attached to the one or more dies.
12. The power module of clause 10 or clause 11, further comprising:
a second charge pump assembly mounted on the second surface, wherein the second charge pump assembly comprises one or more dies and capacitors mounted on the PCB laminate structure.
13. The power module of any of clauses 1-12, wherein the first charge pump assembly comprises a system-in-package assembly.
14. The power module of any of clauses 1-12, wherein the first charge pump assembly is a molded assembly.
15. The power module of any of clauses 1-12, wherein the first charge pump assembly is unmolded.
16. The power module of any of clauses 1-15, wherein the first board comprises a PCB laminate structure, and the first charge pump assembly comprises one or more bumped dies attached on the PCB laminate structure.
17. The power module of any of clauses 1-15, wherein the first board comprises a PCB laminate structure, and the first charge pump assembly comprises one or more dies embedded in the PCB laminate structure.
18. The power module of any of clauses 1-15, wherein the first board comprises a PCB laminate structure, and the first charge pump assembly comprises one or more dies mounted on a leadframe.
19. The power module of any of clauses 1-18, further comprising:
a carrier board connected to the first board, the carrier board comprising the bottom surface for mounting the power module to the circuit board.
20. The power module of clause 19, wherein the carrier board is configured to provide a land grid array or a ball grid array on the bottom surface, or on a leadframe structure.
21. The power module of any of clauses 1-15, wherein the first board is a rigid PCB section of a rigid flex board, the rigid flex board being bent and mounted to the carrier board.
22. A power module, comprising:
a bottom surface for mounting the power module to a circuit board; and
a plurality of circuit assemblies stacked along a first direction parallel to the bottom surface, the plurality of circuit assemblies providing a plurality of charge pump circuits coupled in parallel and configured to convert an input voltage to an output voltage.
23. The power module of clause 22, further comprising:
a plurality of substrates aligned along the first direction, each of the plurality of substrates comprising a first surface and a second surface opposite to each other and perpendicular to the bottom surface;
wherein each of the plurality of circuit assemblies is mounted on the first surface or the second surface of one corresponding substrate of the plurality of substrates.
24. The power module of clause 22 or 23, further comprising:
a plurality of heatsink structures, wherein one of the plurality of heatsink structures is placed between two adjacent circuit assemblies of the plurality of circuit assemblies along the first direction.
25. The power module of any of clauses 22-24, wherein one or more of the plurality of circuit assemblies comprise:
a first active device layer including a plurality of first switches of a corresponding charge pump circuit;
a passive device layer attached to the first active device layer, the passive device layer including a plurality of capacitors of the corresponding charge pump circuit; and
a second active device layer attached to the passive device layer, the second active device layer including a plurality of second switches of the corresponding charge pump circuit.
26. The power module of clause 25, wherein the plurality of first switches are stack switches, and the plurality of second switches are phase switches.
27. The power module of clause 25 or 26, wherein the passive device layer comprises a glass wafer.
28. The power module of any of clauses 25-27, wherein the one or more of the plurality of circuit assemblies further comprise:
one or more heat spreader layers comprising a thermally conductive insulating material.
29. The power module of any of clauses 22-28, wherein one or more of the plurality of circuit assemblies comprise:
a first device layer including a plurality of first switches;
a second device layer including a plurality of second switches; and
a third device layer disposed between the first device layer and the second device layer, the third device layer including a plurality of first capacitors,
wherein the plurality of first switches and the plurality of second switches are interconnected with the plurality of first capacitors to form a corresponding charge pump circuit.
30. The power module of clause 29, wherein the plurality of first switches are stack switches coupled to positive terminals of the plurality of first capacitors via a plurality of direct current (dc) nodes; and
wherein the plurality of second switches are phase switches coupled to negative terminals of the plurality of first capacitors via a first phase node or a second phase node.
31. The power module of clause 30, wherein the first phase node is coupled to negative terminals of a first subset of the plurality of first capacitors, and the second phase node is coupled to negative terminals of a second subset of the plurality of first capacitors.
32. The power module of any of clauses 29-31, wherein one or more of the plurality of circuit assemblies further comprise:
a fourth device layer including a plurality of third switches; and
a fifth device layer disposed between the second device layer and the fourth device layer, the fifth device layer including a plurality of second capacitors,
wherein the plurality of second switches are phase switches for a first phase and a second phase, to connect the plurality of first capacitors and the plurality of second capacitors to shared phase nodes of the charge pump circuit;
wherein the plurality of first switches are stack switches associated with the first phase; and
wherein the plurality of third switches are stack switches associated with the second phase.
33. The power module of any of clauses 29-32, wherein positive terminals of the plurality of first capacitors are coupled to corresponding contacts located on a first surface of the third device layer, and negative terminals of the plurality of first capacitors are coupled to corresponding contacts located on a second surface of the third device layer opposite the first surface.
34. The power module of any of clauses 29-33, wherein the plurality of first capacitors are multi-layer ceramic capacitors.
35. The power module of any of clauses 29-34, wherein the third device layer further includes an inductor coupled with one or more of the plurality of first capacitors.
36. The power module of any of clauses 29-35, wherein one or more of the plurality of circuit assemblies further comprise:
an inductor layer stacked adjacent to the third device layer, the inductor layer including an inductor coupled with one or more of the plurality of first capacitors to form a resonant charge pump or a multi-level charge pump.
37. A computer device, comprising:
a motherboard; and
a power supply unit electrically coupled to the motherboard via electrical connections to deliver power to one or more electrical devices on the motherboard, the power supply unit comprising a power module configured to convert an input power to an output power, the power module comprising:
a first board connected to a bottom surface providing electrical connections to the motherboard, the first board comprising a first surface and a second surface opposite to each other and perpendicular to the bottom surface;
a first charge pump assembly mounted on the first surface, the first charge pump assembly comprising a first power conversion circuit configured to convert an input voltage to an output voltage; and
a first heatsink structure arranged adjacent to the first charge pump assembly, the first charge pump assembly being placed between the first heatsink structure and the first board.
38. A power conversion circuit, comprising:
a plurality of switched capacitor circuits coupled in parallel to convert a first voltage to a second voltage, a switched capacitor circuit of the plurality of switched capacitor circuits comprising:
a plurality of fly capacitors;
a plurality of stack switches coupled to positive terminals of the plurality of fly capacitors via a plurality of direct current (dc) nodes; and
a plurality of phase switches coupled to negative terminals of the plurality of fly capacitors via a first phase node or a second phase node of the switched capacitor circuit,
wherein the switched capacitor circuit is configured to transition between different states in response to switching of the plurality of stack switches and the plurality of phase switches to convert the first voltage to the second voltage,
wherein the plurality of switched capacitor circuits are respectively capable of being arranged in a plurality of circuit assemblies in a power module with a bottom surface for mounting the power module to a circuit board and providing electrical connections, the plurality of circuit assemblies being stacked along a first direction parallel to the bottom surface.
39. A method for assembling a power module, comprising:
mounting a first charge pump assembly on a first surface of a first board, the first charge pump assembly comprising a first power conversion circuit configured to convert an input voltage to an output voltage; and
mounting the first board and positioning the first surface to be perpendicular to a bottom surface of the power module.
40. The method of clause 39, further comprising:
attaching a first heatsink structure to place the first charge pump assembly between the first heatsink structure and the first board.
41. The method of clause 39 or 40, further comprising:
mounting a second charge pump assembly on a second surface of the first board, the second charge pump assembly comprising a second power conversion circuit configured to convert the input voltage to the output voltage, the first surface and the second surface being opposite to each other; and
attaching a second heatsink structure to place the second charge pump assembly between the second heatsink structure and the first board.
42. The method of any of clause 39-41, further comprising:
mounting a third charge pump assembly on a third surface of a second board, the third charge pump assembly comprising a third power conversion circuit configured to convert the input voltage to the output voltage; and
mounting the second board and positioning the third surface to be perpendicular to the bottom surface.
43. The method of clause 42, further comprising:
mounting a fourth charge pump assembly on a fourth surface of the second board, the fourth charge pump assembly comprising a fourth power conversion circuit configured to convert the input voltage to the output voltage, the third surface and the fourth surface being opposite to each other.
44. The method of clause 42 or 43, further comprising:
assembling a heatsink unit comprising a plurality of heatsink structures parallel to each other; and
attaching the heatsink unit to place the first board between a first heatsink structure and a second heatsink structure, and to place the second board between the second heatsink structure and a third heatsink structure.
45. The method of any of clause 42-44, wherein mounting the first board and mounting the second board comprises:
connecting the first board and the second board with a rigid flex board;
mounting the rigid flex board; and
positioning the first board and the second board to be perpendicular to the bottom surface.
46. The method of any of clause 39-45, wherein the first board is mounted on a carrier board by using a land grid array or a ball grid array.
47. The method of any of clause 39-45, wherein the first board is mounted on a carrier board by using a leadframe structure.
48. The method of any of clause 39-45, wherein the first board is a rigid printed circuit board (PCB) section of a rigid flex board, and the rigid flex board is mounted on a carrier board by using one or more solder pins.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A power module, comprising:
a first board comprising a first surface and a second surface opposite to each other and perpendicular to a bottom surface of the power module for mounting the power module to a circuit board, the bottom surface providing electrical connections to the circuit board;
a first charge pump assembly mounted on the first surface, the first charge pump assembly comprising a first power conversion circuit configured to convert an input voltage to an output voltage; and
a first vertical heatsink structure arranged adjacent to the first charge pump assembly, the first charge pump assembly being placed between the first vertical heatsink structure and the first board.

2. The power module of claim 1, further comprising:
a second charge pump assembly mounted on the second surface, the second charge pump assembly comprising a second power conversion circuit configured to convert the input voltage to the output voltage; and
a second vertical heatsink structure arranged adjacent to the second charge pump assembly, the second charge pump assembly being placed between the second vertical heatsink structure and the first board,
wherein the first and the second power conversion circuits are electrically coupled to each other in parallel.

3. The power module of claim 2, further comprising:
a second board arranged parallel to the first board, the second board comprising a third surface and a fourth surface opposite to each other and perpendicular to the bottom surface;
a third charge pump assembly mounted on the third surface, the third charge pump assembly comprising a third power conversion circuit configured to convert the input voltage to the output voltage;
wherein the second vertical heatsink structure is arranged between the second charge pump assembly and the third charge pump assembly.

4. The power module of claim 3, further comprising:
a fourth charge pump assembly mounted on the fourth surface, the fourth charge pump assembly comprising a fourth power conversion circuit configured to convert the input voltage to the output voltage; and
a third vertical heatsink structure arranged adjacent to the fourth charge pump assembly, the fourth charge pump assembly being placed between the third vertical heatsink structure and the second board,
wherein the third and the fourth power conversion circuits are electrically coupled in parallel to the first and the second power conversion circuits.

5. The power module of claim 3, further comprising:
a horizontal heatsink structure connected to the first vertical heatsink structure, the second vertical heatsink structure, and the third vertical heatsink structure.

6. The power module of claim 1, wherein the first charge pump assembly comprises:
a first integrated circuit mounted on the first surface, the first integrated circuit comprising a plurality of stack switches of the first power conversion circuit;
a second integrated circuit mounted on the first surface and electrically connected to the first integrated circuit via a bus bar, the second integrated circuit comprising a plurality of phase switches of the first power conversion circuit; and
a plurality of fly capacitors of the first power conversion circuit coupled between the first integrated circuit and the second integrated circuit.

7. The power module of claim 6, wherein a distance of the first integrated circuit to the bottom surface is greater than a distance of the second integrated circuit to the bottom surface.

8. The power module of claim 6, wherein the first integrated circuit further comprises a controller configured to control the stack switches and the phase switches.

9. The power module of claim 6, further comprising:
a controller mounted on the second surface and configured to control the stack switches and the phase switches.

10. The power module of claim 1, wherein the first board comprises a printed circuit board (PCB) laminate structure, and the first charge pump assembly comprises one or more dies and capacitors mounted on the PCB laminate structure.

11. The power module of claim 10, wherein the first charge pump assembly further comprises one or more heat spreader layers attached to the one or more dies.

12. The power module of claim 10, further comprising:
a second charge pump assembly mounted on the second surface, wherein the second charge pump assembly comprises one or more dies and capacitors mounted on the PCB laminate structure.

13. The power module of claim 12, wherein the first charge pump assembly comprises a system-in-package assembly.

14. The power module of claim 12, wherein the first charge pump assembly is a molded assembly.

15. The power module of claim 12, wherein the first charge pump assembly is unmolded.

16. The power module of claim 1, wherein the first board comprises a PCB laminate structure, and the first charge pump assembly comprises one or more bumped dies attached on the PCB laminate structure.

17. The power module of claim 1, wherein the first board comprises a PCB laminate structure, and the first charge pump assembly comprises one or more dies embedded in the PCB laminate structure.

18. The power module of claim 1, wherein the first board comprises a PCB laminate structure, and the first charge pump assembly comprises one or more dies mounted on a leadframe.

19. The power module of claim 1, further comprising:
a carrier board connected to the first board, the carrier board comprising the bottom surface for mounting the power module to the circuit board.

20. The power module of claim 19, wherein the carrier board is configured to provide a land grid array or a ball grid array on the bottom surface, or on a leadframe structure.

21. The power module of claim 1, wherein the first board is a rigid PCB section of a rigid flex board, the rigid flex board being bent and mounted to the carrier board.
